(19) United States
(12) Patent Application Publication
(10) Pub. No.: US 2012/0282549 A1
(43) Pub. Date: Nov. 8, 2012

(54) PHOTOSENSITIVE COMPOSITION, PHOTOSENSITIVE FILM, PHOTOSENSITIVE LAMINATE, METHOD FOR FORMING PERMANENT PATTERN, AND PRINTED BOARD

(75) Inventors: Hideki Tomizawa, Ashigarakami-gun (JP); Kazumori Minami, Ashigarakami-gun (JP); Daisuke Arioka, Ashigarakami-gun (JP)

(73) Assignee: FUJIFILM CORPORATION, Minato-ku, Tokyo (JP)

(21) Appl. No.: 13/522,227

(22) PCT Filed: Jan. 28, 2011
(86) PCT No.: PCT/JP2011/051749

§ 371 Date: Jul. 13, 2012

(30) Foreign Application Priority Data
Feb. 1, 2010 (JP) 2010-020524

(51) Int. Cl. G03F 7/004; G03F 7/20

(52) U.S. Cl. 430/284.1; 430/322

(57) ABSTRACT

A photosensitive composition including: a photosensitive polyurethane resin; a phosphorus-containing flame retardant; a polymerizable compound; and a photopolymerization initiator, wherein the photosensitive polyurethane resin contains an ethylenically unsaturated bond group and a carboxyl group, and contains a polyurethane skeleton which contains a polyol group as a repeating unit.

### TECHNICAL FIELD

The present invention relates to a photosensitive composition suitable as solder resist materials used for a flexible circuit board, a photosensitive film, a photosensitive laminate, a method for forming a permanent pattern, and a printed board using the photosensitive composition.

### BACKGROUND ART

Conventionally, in the formation of permanent patterns such as solder resists, a photosensitive film formed by coating a photosensitive composition on a support and drying the coating to form a photosensitive layer have been used. Methods for the formation of permanent patterns such as solder resists include, for example, a method that includes: laminating a photosensitive film on a substrate such as a copper-clad laminate, on which a permanent pattern is to be formed, to form a laminate; exposing the photosensitive layer in the laminate to light; after the exposure, developing the photosensitive layer to form a pattern; and then subjecting the pattern to curing treatment to form a permanent pattern.

For a photosensitive composition using a polyurethane resin as a binder for the solder resist, improving folding resistance and flame retardancy is an important task to be achieved, and various studies have been made in this regard.

For example, a photosensitive composition has been proposed that contains (A) an acid-modified vinyl group-containing novolac type epoxy resin having a biphenyl skeleton, (B) a polyurethane resin, (C) a phosphorus-containing compound, (D) a photopolymerizable compound having at least one ethylenically unsaturated bond group in a molecule thereof, and (E) a photopolymerization initiator, in which (B) the polyurethane resin is a reaction product of an epoxy acrylate compound having an ethylenically unsaturated bond group and two or more hydroxyl groups, a diisocyanate compound, and a diol compound having a carboxyl group (see PTL 1).

In addition, a photosensitive composition for a rigid printed wiring board has been proposed that contains a photosensitive urethane resin (A), a photopolymerization initiator (B), an ethylenically unsaturated group-containing photosensitive compound (C), and a thermal curable compound (D), in which the photosensitive urethane resin (A) is a resin prepared by reacting a carboxyl group in a carboxyl group-containing urethane prepolymer (a) obtained by reacting a polymer polyol (e), a carboxylic acid compound having two hydroxyl groups in a molecule thereof (f), and a diisocyanate compound (g) as essential components, with an epoxy group or an oxetane group in a compound (b) having an epoxy group or an oxetane group and an ethylenically unsaturated group, and reacting a hydroxyl group in the resultant hydroxyl group-containing urethane prepolymer (c) with an acid anhydride group in an acid anhydride group-containing compound (d) (see PTL 2). PTL 2 describes in Examples a polyurethane resin containing a phosphazene compound or a polyphosphoric acid melamine salt.

Therefore, although it is required for a photosensitive composition used for a flexible circuit board to have excellent flame retardancy as well as excellent folding resistance, the flame retardancy and folding resistance are in the relationship of trade-off. Thus, there has not been developed yet a photosensitive composition having both of excellent flame retardancy and excellent folding resistance, a photosensitive film, a photosensitive laminate, a method of forming a permanent pattern, and a printed board using the photosensitive composition.

### CITATION LIST

### Patent Literature

PTL 1: Japanese Patent Application Laid-Open (JP-A) No. 2009-251585
PTL 2: JP-A No. 2009-271290

### SUMMARY OF INVENTION

### Technical Problem

The present invention has been made under such circumstances, and aims to solve the above-described various problems of the prior art and attain the following object. An object of the present invention is to provide a photosensitive composition having excellent folding resistance and excellent flame retardancy, and a photosensitive film, a photosensitive laminate, a method for forming a permanent pattern, and a printed board using the photosensitive composition.

### Solution to Problem

The above object can be attained by the following means.

<1> A photosensitive composition including:

a photosensitive polyurethane resin;

a phosphorus-containing flame retardant;

a polymerizable compound; and

a photopolymerization initiator,

wherein the photosensitive polyurethane resin contains an ethylenically unsaturated bond group and a carboxyl group, and contains a polyurethane skeleton which contains a polyol group as a repeating unit.

<2> The photosensitive composition according to <1>, wherein the ethylenically unsaturated group is a (meth)acrylate group.

<3> The photosensitive composition according to <1> or <2>, wherein the photosensitive polyurethane resin is obtained by reacting together a polymer polyol compound, a diisocyanate compound, a (meth)acrylate compound having two hydroxy groups in a molecule thereof, and a carboxylic acid having two hydroxy groups in a molecule thereof.

<4> The photosensitive composition according to <3>, wherein the polymer polyol compound is a polypropylene glycol.

<5> The photosensitive composition according to <3> or <4>, wherein the polymer polyol compound has a mass average molecular weight of 400 to 3,000.

<6> The photosensitive composition according to any one of <3> to <5>, wherein the diisocyanate compound is an aromatic compound.

<7> The photosensitive composition according to any one of <3> to <6>, wherein the diisocyanate compound is a diisocyanate compound having a bisphenol A skeleton, a bisphenol F skeleton, a bisphenyl skeleton, a naphthalene skeleton, a phenanthrene skeleton, or an anthracene skeleton.

<8> The photosensitive composition according to any one of <1> to <7>, wherein the phosphorus-containing flame retardant is a condensed phosphoric acid compound, a polyphosphoric acid melamine salt, a phosphazene compound, and a metal phosphate.

<9> The photosensitive composition according to any one of <1> to <8>, further including a thermal crosslinking agent.

<10> A photosensitive film including:

a support; and

a photosensitive layer which contains the photosensitive composition according to any one of <1> to <9>, the photosensitive layer being provided on the support.

<11> A photosensitive laminate including:

a substrate; and

a photosensitive layer which contains the photosensitive composition according to any one of <1> to <9>, the photosensitive layer being provided on the substrate.

<12> A method for forming a permanent pattern, the method including:

exposing, to light, a photosensitive layer formed of the photosensitive composition according to any one of <1> to <9>.

<13> A printed board including;

a permanent pattern formed by the method for forming a permanent pattern according to <12>.

### Advantageous Effects of Invention

The present invention can solve the above-described various problems of the prior art, and can provide a photosensitive composition having excellent folding resistance and flame retardancy, and a photosensitive film, a photosensitive laminate, a method for forming a permanent pattern, and a printed board using the photosensitive composition.

### DESCRIPTION OF EMBODIMENTS

### Photosensitive Composition

A photosensitive composition of the present invention includes a photosensitive polyurethane resin, a phosphorus-containing flame retardant, a polymerizable compound, and a photopolymerization initiator, and optionally further includes a thermal crosslinking agent and other ingredients.

### <Photosensitive Polyurethane Resin>

The photosensitive polyurethane resin contains an ethylenically unsaturated bond group and a carboxyl group, and contains a polyurethane skeleton which contains a polyol group as a repeating unit.

The photosensitive polyurethane resin is preferably obtained by reacting a polymer polyol compound, a diisocyanate compound, a (meth)acrylate compound having two hydroxy groups in a molecule thereof, and a carboxylic acid having two hydroxy groups in a molecule thereof.

The ethylenically unsaturated bond group in the photosensitive polyurethane resin is not particularly limited and may be properly selected according to the contemplated purposes. For example, it is preferably a (meth)acrylate group, which preferably includes a reactive residue of the (meth)acrylate compound having two hydroxy groups in a molecule thereof described below.

The carboxy group in the photosensitive polyurethane resin is not particularly limited and may be properly selected according to the contemplated purposes. For example, it preferably includes a reactive residue of the carboxylic acid having two hydroxy groups in a molecule thereof described below.

The polyol group in the photosensitive polyurethane resin is not particularly limited and may be properly selected according to the contemplated purposes. For example, it preferably includes a reactive residue of the polymer polyol compound described below.

### —(Meth)Acrylate Compound Having Two Hydroxy Groups in a Molecule Thereof—

The (meth)acrylate compound having two hydroxy groups in a molecule thereof includes a diol compound containing an unsaturated group on the side chain thereof. The diol compounds containing an unsaturated group on a side chain thereof may be trimethylolpropane monoaryl ether, which is commercially available, or compounds that can easily be produced by a reaction of a compound such as a halogenated diol compound, triol compound, or amino diol compound with an unsaturated group-containing compound such as carboxylic acid, acid chloride, isocyanate, alcohol, amine, thiol, or a halogenated alkyl compound.

The diol compound having an unsaturated group on a side chain thereof is not particularly limited and may be properly selected according to contemplated purposes. Examples thereof include compounds described in paragraphs [0057] to in Japanese Patent Application Laid-Open (JP-A) No. 2005-250438 and compounds represented by General formula (G) described in paragraphs [0064] to [0060] in JP-A No. 2005-250438. Among them, compounds represented by General formula (G) described in paragraphs [0064] to [0066] in JP-A No. 2005-250438 are preferred.

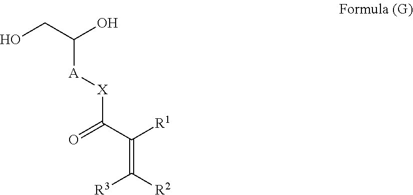

In General formula (G), R¹ to R³ each independently represent a hydrogen atom or a monovalent organic group; A represents a divalent organic residue; X represents an oxygen atom, a sulfur atom, or N(R¹²)—; and R¹² represents a hydrogen atom or a monovalent organic group. R¹ to R³ and X in General formula (G) are as defined in General formula (1) of (i) polyurethane resin having vinyl group on the side chain thereof described below. Preferred embodiments in conjunction with R¹ to R³ and X in General formula (G) are the same as described in connection with General formula (1) of (i) polyurethane resin having vinyl group on the side chain thereof described below.

It is considered that, when polyurethane resins derived from diol compounds represented by General formula (G) are used, the layer strength can be improved by the effect of suppressing excessive molecular movement of the main chain of the polymer attributable to a secondary alcohol having a large steric hindrance.

### —Carboxylic Acid Having Two Hydroxy Groups in a Molecule Thereof—

The carboxylic acid having two hydroxy groups in a molecule thereof (carboxyl group-containing diol compound) is not particularly limited and may be properly selected according to the contemplated purposes. For example, it includes 3,5-dihydroxybenzoic acid, 2,2-bis(hydroxymethyl)propionic acid, 2,2-bis(2-hydroxyethyl)propionic acid, 2,2-bis(3-hydroxypropyl)propionic acid, bis(hydroxymethyl)acetic acid, bis(4-hydroxyphenyl)acetic acid, 2,2-bis(hydroxymethyl)butyric acid, 4,4-bis(4-hydroxyphenyl)pentanoic acid, tartaric acid, N,N-dihydroxyethylglycine, N,N-bis(2-hydroxyethyl)-3-carboxy-propionamide. One type of these carboxyl group-containing diol compounds may be used, or alternatively, two or more types of these carboxyl group-containing diol compounds may be used in combination.

### —Polymer Polyol Compound—

The polymer polyol compound is not particularly limited and may be properly selected according to the contemplated purposes. For example, it includes polyether polyols such as polyethylene glycol, polypropylene glycol, polyethylene oxide, polypropylene oxide, a block copolymer or random copolymer of ethylene oxide/propylene oxide, polytetramethylene glycol, and a block copolymer or random copolymer of tetramethylene glycol and neopentyl glycol; polyester polyols which is a condensate of a polyol or polyether polyol with a polybasic acid such as maleic anhydride, maleic acid, fumaric acid, itaconic anhydride, itaconic acid, adipic acid, and isophthalic acid; polycarbonate polyols obtained by reacting glycols or bisphenols with carbonic esters, or treating glycols or bisphenols with phosgene in the presence of alkali; caprolactone-modified polyols such as caprolactone-modified polytetramethylene polyol; polyolefin polyols; polybutadiene polyols such as hydrogenated polybutadiene polyol; and silicone polyol. One type of these polymer polyol compounds may be used, or alternatively, two or more types of these polymer polyol compounds may be used in combination. Among them, a polypropylene glycol having a mass average molecular weight of 1,000 or more is particularly preferable from the viewpoints of folding resistance and developability.

The mass average molecular weight of the polymer polyol compound is preferably 400 to 3,000, more preferably 800 to 1,500. When the mass average molecular weight is less than 400, folding resistance and developability may be insufficient. When the mass average molecular weight is more than 3,000, the reduced glass transition temperature (TO of the resultant photosensitive polyurethane resin may deteriorate insulating reliability thereof.

The mass average molecular weight may be measured with a high-performance gel permeation chromatography (GPC) (HLC-802A, manufactured by TOSOH Co., Ltd.). A 0.5% by mass THF solution is used as a sample solution. One column of TSKgel HZM-M is provided. The sample (200 μL) is injected and eluted with the THF solution, followed by measurement at 25° C. with a refractive index detector or a UV detector (detection wavelength 254 nm).

### —Diisocyanate Compound—

The diisocyanate compound is not particularly limited and may be properly selected according to the contemplated purposes. However, an aromatic diisocyanate compound is preferable because it increases the decomposition temperature of the photosensitive polyurethane resin upon burning.

The aromatic diisocyanate compound is preferably a diisocyanate compound having a bisphenol A skeleton, a bisphenol F skeleton, a bisphenyl skeleton, a naphthalene skeleton, a phenanthrene skeleton, or an anthracene skeleton.

The diisocyanate compound having a bisphenol A skeleton includes a compound represented by the following structural formula wherein R¹ may include a hydrogen atom or an alkyl group having 2 to 5 carbon atoms.

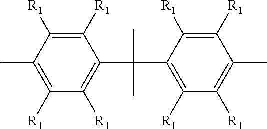

The diisocyanate compound having a bisphenol F skeleton includes a compound represented by the following structural formula wherein R² may include a hydrogen atom or an alkyl group having 2 to 5 carbon atoms.

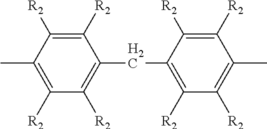

The diisocyanate compound having a bisphenyl skeleton includes a compound represented by the following structural formula wherein R³ may include a hydrogen atom or an alkyl group having 2 to 5 carbon atoms.

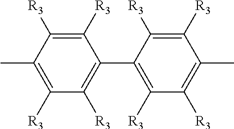

The diisocyanate compound having a naphthalene skeleton includes a compound represented by the following structural formula wherein any two of R₄ include an isocyanate group, and the remaining R₄ may include a hydrogen atom or an alkyl group having 2 to 5 carbon atoms.

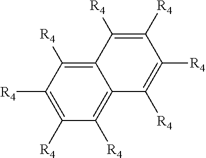

The diisocyanate compound having a phenanthrene skeleton includes a compound represented by the following structural formula wherein any two of R₅ include an isocyanate group, and the remaining R₅ may include a hydrogen atom or an alkyl group having 2 to 5 carbon atoms.

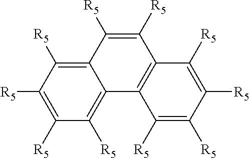

The diisocyanate compound having an anthracene skeleton includes a compound represented by the following structural formula wherein any two of R₆ are isocyanate groups, and the remaining R₆ may include a hydrogen atom or an alkyl group having 2 to 5 carbon atoms.

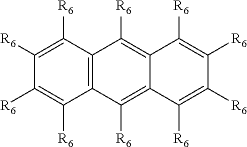

The photosensitive polyurethane resin is not particularly limited and may be properly selected according to contemplated purposes. However, it is preferably acid-modified vinyl group-containing polyurethane resin described below.

### <<Acid-Modified Vinyl Group-Containing Polyurethane Resin>>

The acid-modified vinyl group-containing polyurethane resin is not particularly limited and may be properly selected according to contemplated purposes. Examples of such acid-modified vinyl group-containing polyurethane resin include (i) polyurethane resins having an ethylenically unsaturated bond on a side chain thereof and (ii) polyurethane resins obtained by reacting a carboxyl group-containing polyurethane with a compound having an epoxy group and a vinyl group in a molecule thereof.

### —(i) Polyurethane Resin Having Vinyl Group on Side Chain Thereof—

The urethane resin having vinyl group on the side chain thereof is not particularly limited and may be properly selected according to contemplated purposes. Examples of such polyurethane resins having vinyl group on the side chain thereof include polyurethane resins having at least one of functional groups represented by General formulae (1) to (3).

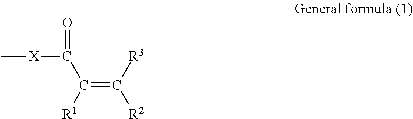

In General formula (1), R¹ to R³ each independently represents a hydrogen atom or a monovalent organic group. R¹ is not particularly limited and may be properly selected according to contemplated purposes. Examples thereof include a hydrogen atom and optionally substituted alkyl groups. Among them, a hydrogen atom and a methyl group are preferred from the viewpoint of high radical reactivity. R² and R³ are not particularly limited and may be properly selected according to contemplated purposes. For example, R² and R³ each independently may represent a hydrogen atom, a halogen atom or an amino, carboxyl, alkoxycarbonyl, sulfo, nitro, cyano, optionally substituted alkyl, optionally substituted aryl, optionally substituted alkoxy, optionally substituted aryloxy, optionally substituted alkylamino, optionally substituted arylamino, optionally substituted alkylsulfonyl, or optionally substituted arylsulfonyl group. Among them, a hydrogen atom, carboxyl, alkoxycarbonyl, optionally substituted alkyl, and optionally substituted aryl groups are preferred from the viewpoint of high radical reactivity.

In General formula (1), X represents an oxygen atom, a sulfur atom, or —N(R¹²)—. R¹² represents a hydrogen atom or a monovalent organic group. R¹² is not particularly limited and may be properly selected according to contemplated purposes. Examples thereof include optionally substituted alkyl groups. Among them, a hydrogen atom and a methyl group, an ethyl group, and an isopropyl group are preferred from the viewpoint of high radical reactivity.

The substituents that can be introduced are not particularly limited and may be properly selected according to contemplated purposes. Examples thereof include alkyl, alkenyl, alkynyl, aryl, alkoxy, aryloxy, a halogen atom, amino, alkylamino, aryl amino, carboxyl, alkoxycarbonyl, sulfo, nitro, cyano, amide, alkylsulfonyl, and arylsulfonyl.

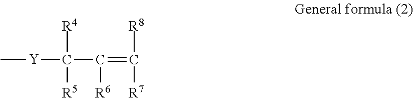

In General formula (2), R⁴ to R⁸ each independently represents a hydrogen atom or a monovalent organic group. R⁴ to R⁸ are not particularly limited and may be properly selected according to contemplated purposes. Examples thereof include a hydrogen atom, a halogen atom, and amino, dialkylamino, carboxyl, alkoxycarbonyl, sulfo, nitro, cyano, optionally substituted alkyl, optionally substituted aryl, optionally substituted alkoxy, optionally substituted aryloxy, optionally substituted alkylamino, optionally substituted arylamino, optionally substituted alkylsulfonyl, and optionally substituted arylsulfonyl. Among them, a hydrogen atom, carboxyl, alkoxycarbonyl, optionally substituted alkyl, and optionally substituted aryl groups are preferred from the viewpoint of high radical reactivity.

The substituents that can be introduced may be the same as those in General formula (1). Y represents an oxygen atom, a sulfur atom, or —N(R¹²)—. R¹² is as defined in General formula (1), and preferred examples thereof are the same as those in General formula (1).

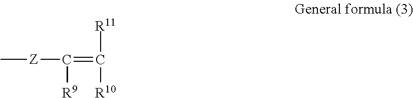

In General formula (3), R⁹ to R¹¹ each independently represent a hydrogen atom or a monovalent organic group. In General formula (3), R⁹ is not particularly limited and may be properly selected according to contemplated purposes. Examples thereof include a hydrogen atom or optionally substituted alkyl. Among them, a hydrogen atom and a methyl group are preferred from the viewpoint of high radical reactivity. In General formula (3), R¹⁰ and R¹¹ are not particularly limited and may be properly selected according to contemplated purposes. Examples thereof include a hydrogen atom, a halogen atom, and amino, dialkylamino, carboxyl, alkoxycarbonyl, sulfo, nitro, cyano, optionally substituted alkyl, optionally substituted aryl, optionally substituted alkoxy, optionally substituted aryloxy, optionally substituted alkylamino, optionally substituted aryl amino, optionally substituted alkylsulfonyl, and optionally substituted arylsulfonyl. Among them, a hydrogen atom and carboxyl, alkoxycarbonyl, optionally substituted alkyl and optionally substituted aryl groups are preferred from the viewpoint of high radical reactivity.

Examples of substituents that can be introduced include those as defined in General formula (1). Z represents an oxygen atom, a sulfur atom, —N(R¹³)—, or an optionally substituted phenylene group. R¹³ is not particularly limited and may be properly selected according to contemplated purposes. Example thereof includes a optionally substituted alkyl group. Among them, a methyl group, an ethyl group, and an isopropyl group are preferred from the viewpoint of high radical reactivity.

The urethane resin having an ethylenically unsaturated bond on a side chain thereof is a polyurethane resin having a basic skeleton including structural units represented by a reaction product between at least one of diisocyanate compound represented by General formula (4) and at least one of diol compound represented by General formula (5).

OCN—X⁰—NCO General formula (4)

HO—Y⁰—OH General formula (5)

In General formulae (4) and (5), X⁰ and Y⁰ each independently represent a divalent organic residue.

When at least one of diisocyanate compounds represented by General formula (4) and diol compounds represented by General formula (5) has at least one of groups represented by General formulae (1) to (3), polyurethane resins having side chains into which groups represented by General formulae (1) to (3) have been introduced are produced as reaction products between the diisocyanate compounds and the diol compounds. According to this method, polyurethane resins having side chains into which groups represented by General formulae (1) to (3) have been introduced can be more easily produced than in a method, after the production of a polyurethane resin by a reaction, a desired side chain is substituted or introduced.

The diisocyanate compound represented by General formula (4) is not particularly limited and may be properly selected according to contemplated purposes. Examples thereof include products obtained by subjecting a triisocyanate compound to an addition reaction with one equivalent of a monofunctional alcohol having an unsaturated group or a monofunctional amine compound.

The triisocyanate compound is not particularly limited and may be properly selected according to contemplated purposes. Examples thereof include compounds described in paragraphs [0034] and [0035] in JP-A No. 2005-250438.

The monofunctional alcohol having an unsaturated group or a monofunctional amine compound is not particularly limited and may be properly selected according to contemplated purposes. Examples thereof include compounds described in paragraphs [0037] to [0040] in JP-A No. 2005-250438.

The unsaturated group may be introduced into a side chain in the polyurethane resin by any method without particular limitation, and the method may be properly selected according to contemplated purposes. A method using a diisocyanate compound having an unsaturated group on a side chain thereof is preferred as a starting material for the production of polyurethane resins. The diisocyanate compound is not particularly limited and may be properly selected according to contemplated purposes. Examples thereof include compounds that are diisocyanate compounds obtainable by subjecting a triisocyanate compound to an addition reaction with one equivalent of a monofunctional alcohol having an unsaturated group or a monofunctional amine compound. Examples thereof include compounds having an unsaturated group on a side chain described in paragraphs [0042] to [0049] in JP-A No. 2005-250438.

The polyurethane resin having an ethylenically unsaturated bond on a side chain thereof may also be copolymerized with a diisocyanate compound other than the diisocyanate compound containing an unsaturated group from the viewpoints of improving compatibility with other ingredients in the polymerizable composition and improving the storage stability.

The diisocyanate compound to be copolymerized is not particularly limited and may be properly selected according to contemplated purposes. Examples thereof include diisocyanate compounds represented by General formula (6).

OCN-L¹-NCO General formula (6)

In General formula (6), L¹ represents an optionally substituted divalent aliphatic or aromatic hydrocarbon group. If necessary, L¹ may have other functional group, for example, an ester, urethane, amide, or ureido group that is not reactive with the isocyanate group.

The diisocyanate compound represented by General formula (6) is not particularly limited and may be properly selected according to contemplated purposes. Examples thereof include aromatic diisocyanate compounds such as 2,4-tolylene diisocyanate, a dimer of 2,4-tolylene diisocyanate, 2,6-tolylenedilene diisocyanate, p-xylylene diisocyanate, m-xylylene diisocyanate, 4,4′-diphenylmethane diisocyanate, 1,5-naphthylene diisocyanate, and 3,3′-dimethylbiphenyl-4,4′-diisocyanate; aliphatic diisocyanate compounds such as hexamethylene diisocyanate, trimethylhexamethylene diisocyanate, lysine diisocyanate, and dimer acid diisocyanate; alicyclic diisocyanate compounds such as isophorone diisocyanate, 4,4′-methylenebis(cyclohexyl isocyanate), methylcyclohexane-2,4-(or -2,6-) diisocyanate, and 1,3-(isocyanate methyl)cyclohexane; and diisocyanate compounds that are a reaction product between a diol and a diisocyanate such as an addition product of one mole of 1,3-butylene glycol and 2 moles of tolylene diisocyanate.

The diol compounds represented by General formula (5) are not particularly limited and may be properly selected according to contemplated purposes. Examples thereof include polyether diol compounds, polyester diol compounds, and polycarbonates diol compounds.

In order to introduce an unsaturated group into a side chain in the polyurethane resin, in addition to the above method, a method is preferably adopted in which a diol compound having an unsaturated group on a side chain thereof is used as the starting material for the production of the polyurethane resin. Examples such diol compounds containing an unsaturated group on a side chain thereof include trimethylolpropane monoaryl ether, which is commercially available, or compounds that can easily be produced by a reaction of a compound such as a halogenated diol compound, triol compound, or amino diol compound with an unsaturated group-containing compound such as carboxylic acid, acid chloride, isocyanate, alcohol, amine, thiol, or a halogenated alkyl compound. The diol compound having an unsaturated group on a side chain thereof is not particularly limited and may be properly selected according to contemplated purposes. Examples thereof include compounds described in paragraphs [0057] to [0060] in JP-A No. 2005-250438 and compounds represented by General formula (G) described in paragraphs [0064] to [0066] in JP-A No. 2005-250438. Among them, compounds represented by General formula (G) described in paragraphs [0064] to [0066] in JP-A No. 2005-250438 are preferred.

It is considered that, when polyurethane resins derived from diol compounds represented by General formula (G) are used, the layer strength can be improved by the effect of suppressing excessive molecular movement of the main chain of the polymer attributable to a secondary alcohol having a large steric hindrance.

The polyurethane resin having an ethylenically unsaturated bond on a side chain thereof may also be copolymerized with a diol compound other than the diol compound having an unsaturated group on a side chain thereof from the viewpoints of improving compatibility with other ingredients in the polymerizable composition and improving the storage stability.

The diol compound other than the diol compound having an unsaturated group on a side chain thereof are not particularly limited and may be properly selected according to contemplated purposes. Examples thereof include polyether diol compounds, polyester diol compounds, and polycarbonate diol compounds.

The polyether diol compound is not particularly limited and may be properly selected according to contemplated purposes. Examples thereof include compounds described in paragraphs [0068] to [0076] in JP-A No. 2005-250438. The polyester diol compound is not particularly limited and may be properly selected according to contemplated purposes. Examples thereof include compounds described in paragraphs [0077] to [0079] and compounds described as Nos. 1 to 8 and Nos. 13 to 18 in paragraphs [0083] to [0085] in JP-A No. 2005-250438.

The polycarbonate diol compound is not particularly limited and may be properly selected according to contemplated purposes. Examples thereof include compound Nos. 9 to 12 described in paragraphs [0080], [0081] and [0084] of JP-A No. 2005-250438.

In the synthesis of the polyurethane resin having an ethylenically unsaturated bond on a side chain thereof, the diol compound may also be used in combination with a diol compound having a substituent nonreactive with the isocyanate group.

The diol compound having a substituent nonreactive with the isocyanate is not particularly limited and may be properly selected according to contemplated purposes. Examples thereof include compounds described in paragraphs [0087] and [0088] in JP-A No. 2005-250438.

Further, in the synthesis of the polyurethane resin containing an ethylenically unsaturated bond on a side chain thereof, the diol compound may also be used in combination with a diol compound having a carboxyl group. Examples of the diol compound having a carboxyl group include compounds represented by the following General formulae (X) to (Z).

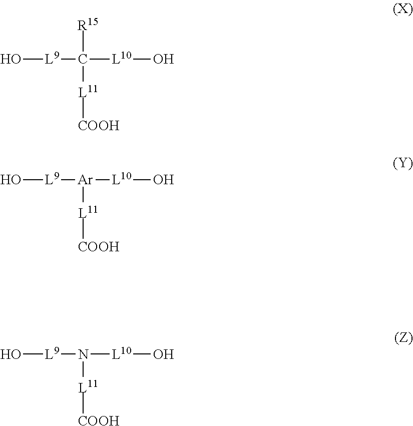

In General formulae (X) to (Z), R¹⁵ is not particularly limited and may be properly selected according to contemplated purposes, as long as it represents a hydrogen atom or an alkyl, aralkyl, aryl, alkoxy, or aryloxy group optionally substituted, for example, by a cyano group, a nitro group, a halogen atom such as —F, —Cl, —Br, or —I, —CONH₂, —COOR¹⁶, —OR¹⁶, —NHCONHR¹⁶, —NHCOOR¹⁶, —NHCOR¹⁶, or —OCONHR¹⁶ wherein R¹⁶ represents an alkyl group having 1 to 10 carbon atoms or an aralkyl group having 7 to 15 carbon atoms. Preferably, R¹⁵ represents a hydrogen atom, an alkyl group having 1 to 8 carbon atoms, or an aryl group having 6 to 15 carbon atoms.

In General formulae (X) to (Z), L⁹, L¹⁰, and L¹¹, which may be the same or different, are not particularly limited and may be properly selected according to contemplated purposes, as long as they represent a single bond or a divalent aliphatic or aromatic hydrocarbon group optionally substituted, for example, by an alkyl, aralkyl, aryl, alkoxy, or halogeno group. Preferably, L⁹, L¹⁰, and L¹¹ represent an alkylene group having 1 to 20 carbon atoms or an arylene group having 6 to 15 carbon atoms. More preferably, L⁹, L¹⁰, and L¹¹ represent an alkylene group having 1 to 8 carbon atoms. If necessary, other functional group nonreactive with the isocyanate group, for example, a carbonyl, ester, urethane, amide, ureido, or ether group may be present in L⁹ to L¹¹. Two or three of R¹⁵, L⁹, L¹⁰, and L¹¹ together may form a ring.

In General formula (Y), Ar is not particularly limited and may be properly selected according to contemplated purposes, as long as it represents an optionally substituted trivalent aromatic hydrocarbon group. Preferably, Ar represents an aromatic group having 6 to 15 carbon atoms.

The diol compound having a carboxyl group represented by General formulae (X) to (Z) is not particularly limited and may be properly selected according to contemplated purposes. Examples thereof include 3,5-dihydroxybenzoic acid, 2,2-bis(hydroxymethyl)propionic acid, 2,2-bis(2-hydroxyethyl)propionic acid, 2,2-bis(3-hydroxypropyl)propionic acid, bis(hydroxymethyl)acetic acid, bis(4-hydroxyphenyl)acetic acid, 2,2-bis(hydroxymethyl)butyric acid, 4,4-bis(4-hydroxyphenyl)pentanoic acid, tartaric acid, N,N-dihydroxyethylglycine, and N,N-bis(2-hydroxyethyl)-3-carboxy-propionamide. One of these diol compounds having a carboxyl group may be used, or alternatively, two or more types of these diol compounds having a carboxyl group may be used in combination.

The presence of the carboxyl group is preferred because properties such as hydrogen bond properties and alkali solubility can be imparted to the polyurethane resin. More specifically, the polyurethane resin having an ethylenically unsaturated bond group on a side chain thereof is preferably the resin further having a carboxyl group on a side chain thereof. More specifically, the vinyl group on the side chain is preferably 0.05 mmol/g to 1.80 mmol/g, more preferably 0.5 mmol/g to 1.80 mmol/g, particularly preferably 0.75 mmol/g to L60 mmol/g. Further, the presence of a carboxyl group on a side chain is preferred, and the acid value is preferably 20 mgKOH/g to 120 mgKOH/g, more preferably 30 mgKOH/g to 110 mgKOH/g, particularly preferably 35 mgKOH/g to 100 mgKOH/g.

In the synthesis of the polyurethane resin having an ethylenically unsaturated bond on a side chain thereof, the diol compound may be used in combination with a compound obtained by ring-opening a tetracarboxylic acid dianhydride with a diol compound.

The compound obtained by ring-opening a tetracarboxylic acid dianhydride with a diol compound is not particularly limited and may be properly selected according to contemplated purposes. Examples thereof include compounds described in paragraphs [0095] to [0101] in JP-A No. 2005-250438.

The polyurethane resin having an ethylenically unsaturated bond on a side chain thereof is synthesized by heating the diisocyanate compound and diol compound in an aprotic solvent after the addition of a conventional active catalyst depending upon the reactivity. The molar ratio of the diisocyanate compound to the diol compound (Mₐ:M_{b}) used in the synthesis is not particularly limited and may be properly selected according to contemplated purposes. The ratio is preferably 1:1 to 1.2:1, and treatment with, for example, an alcohol or an amine can allow a product having desired properties in terms of molecular weight and viscosity to be finally synthesized without residual isocyanate group.

The amount of the ethylenically unsaturated bond group introduced into the polyurethane resin having an ethylenically unsaturated bond on a side chain thereof is not particularly limited and may be properly selected according to contemplated purposes. The amount of the ethylenically unsaturated bond group introduced in terms of vinyl group equivalent is preferably 0.05 mmol/g to 1.80 mmol/g, more preferably 0.5 mmol/g to 1.80 mmol/g, particularly preferably 0.75 mmol/g to 1.60 mmol/g. Further, in the polyurethane resin having an ethylenically unsaturated bond on a side chain thereof, preferably, in addition to the ethylenically unsaturated bond group, a carboxyl group is introduced into the side chain. The acid value is preferably 20 mgKOH/g to 120 mgKOH/g, more preferably 30 mgKOH/g to 110 mgKOH/g, particularly preferably 35 mgKOH/g to 100 mgKOH/g.

The mass average molecular weight of the polyurethane resin having an ethylenically unsaturated bond on a side chain thereof is not particularly limited and may be properly selected according to contemplated purposes. The mass average molecular weight is preferably 5,000 to 50,000, more preferably 5,000 to 30,000. In particular, when the photosensitive composition according to the present invention is used in a photosensitive solder resist, the photosensitive composition has an excellent capability of dispersing an inorganic filler therein, possesses excellent crack resistance and heat resistance, and can provide excellent developability of non-image areas with an alkaline developing solution.

Polyurethane resins that further additionally have an unsaturated group at a polymer end or a main chain are also suitable as the polyurethane resin having an ethylenically unsaturated bond on a side chain thereof. The presence of an unsaturated group at a polymer end or a main chain can further improve crosslinking reactivity between the photosensitive composition and the polyurethane resin having an ethylenically unsaturated bond on a side chain thereof or between the polyurethane resins having an ethylenically unsaturated bond on a side chain thereof and can increase the strength of a photocured product. Here the unsaturated group particularly preferably has a carbon-carbon double bond from the viewpoint of easiness in the crosslinking reaction.

The unsaturated group may be introduced into the polymer end by the following method. Specifically, in the step of treating the residual isocyanate group at the polymer end with an alcohol or amine compound in the synthesis of the polyurethane resin having ethylenically unsaturated bond on a side chain thereof, an alcohol having an unsaturated group or amine compound may be used. Specific examples of such compounds include compounds exemplified above as a monofunctional alcohol having an unsaturated group or a monofuncitonal amine compounds.

The introduction of the unsaturated group into the side chain of the polymer rather than the polymer end is preferred from the viewpoints of easy regulation of introduction amount to increase the amount of the unsaturated group introduced and an improved crosslinking reaction efficiency.

The ethylenically unsaturated bond group introduced is not particularly limited and may be properly selected according to contemplated purposes. A methacryloyl group, an acryloyl group, and a styryl group are preferred from the viewpoint of the formability of the crosslinking cured film. A methacryloyl group and an acryloyl group are more preferred. A methacryloyl group is particularly preferred from the viewpoint of simultaneously realizing both formation and raw storage stability of the crosslinking cured film.

The amount of the methacryloyl group introduced is not particularly limited and may be properly selected according to contemplated purposes. The amount of the methacryloyl group introduced in terms of vinyl equivalent is preferably 0.05 mmol/g to 1.80 mmol/g, more preferably 0.5 mmol/g to 1.80 mmol/g, particularly preferably 0.75 mmol/g to 1.60 mmol/g.

The unsaturated group may be introduced into the main chain by a method in which a diol compound having an unsaturated group in a main chain direction is used in the synthesis of the polyurethane resin. The diol compound having an unsaturated group in a main chain direction is not particularly limited and may be properly selected according to contemplated purposes. Examples thereof include cis-2-butene-1,4-diol, trans-2-butene-1,4-diol, and polybutadienediol.

The polyurethane resin having an ethylenically unsaturated bond on a side chain thereof can also be used in combination with an alkali-soluble polymer containing a polyurethane resin having a structure different from that of the above specific polyurethane resin. For example, the polyurethane resin having an ethylenically unsaturated bond on a side chain thereof can be used in combination with a polyurethane resin containing an aromatic group on a main chain and/or a side chain thereof.

Specific examples of (i) the polyurethane resin having an ethylenically unsaturated bond on a side chain thereof include polymers of P-1 to P-31 described in paragraphs [0293] to [0310] in JP-A No. 2005-250438. Among them, polymers of P-27 and P-28 described in paragraphs [0308] and [0309] are preferred. —(ii) Polyurethane Resin Obtained by Reacting Carboxyl Group-Containing Polyurethane with Compound Having Epoxy Group and Vinyl Group in a Molecule Thereof—

The polyurethane resin is a polyurethane resin obtained by reacting a carboxyl group-containing polyurethane including a diisocyanate and a carboxylic acid group-containing diol as indispensable components with a compound having an epoxy group and a vinyl group in a molecule thereof. According to contemplated purposes, a low-molecular diol having a mass average molecular weight of 300 or less or a low-molecular diol having a mass average molecular weight of 500 or more, which is a diol component, may be added as a comonomer ingredient.

The polyurethane resin can realize stable dispersibility of the inorganic filler and possesses excellent cracking resistance and impact resistance. Thus, heat resistance, moist heat resistance, adhesion, mechanical properties, and electric characteristics are improved.

The polyurethane resin may be obtained by providing a reaction product of diisocyanates of optionally substituted divalent aliphatic and aromatic hydrocarbons and a carboxylic acid-containing diol having a COOH group and two OH groups through any of a C atom and a N atom as indispensable components and reacting the reaction product with a compound having an epoxy group and a vinyl group in a molecule thereof through a —COO— bond.

The polyurethane resin may also be obtained by providing a reaction product of a diisocyanate represented by General formula (1) and at least one compound selected from carboxylic acid group-containing diols represented by any of General formulae (II-1) to (II-3) as indispensable components and at least one compound selected from high-molecular diols represented by any of General formulae (III-1) to (III-5) and having a mass average molecular weight of 800 to 3,000 according to contemplated purposes and reacting the reaction product with a compound that is represented by any of General formulae (IV-1) to (IV-16) and has an epoxy group and a vinyl group in a molecule thereof.

OCN—R₁—NCO General formula (I)

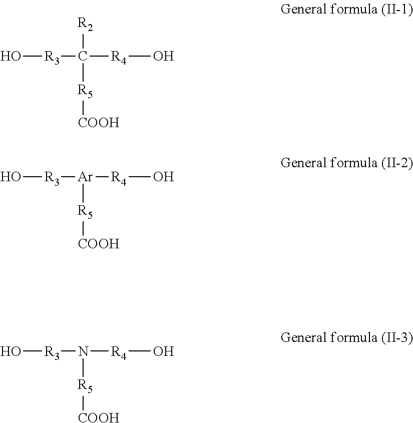

In General formula (1), R¹ represents a divalent aliphatic or aromatic hydrocarbon optionally substituted preferably, for example, by an alkyl group, an aralkyl group, an aryl group, an alkoxy group, or a halogeno group. If necessary, R₁ may have other functional group nonreactive with an isocyanate group, for example, any of an ester group, a urethane group, an amide group, and an ureido group. In General formula (1), R₂ represents a hydrogen atom or an alkyl group, an aralkyl group, an aryl group, an alkoxy group, or an aryloxy group optionally substituted, for example, by a cyano group, a nitro group, a halogen atom (—F, —Cl, —Br, or —I), —CONH₂, —COOR₆, —OR₆, —NHCONHR₆, —NHCOOR₆, —NHCOR₆, —OCONHR₆, or —CONHR₆ wherein R₆ represents any of an alkyl group having 1 to 10 carbon atoms or an aralkyl group having 7 to 15 carbon atoms. Among them, a hydrogen atom, an alkyl group having 1 to 3 carbon atoms, and an aryl group having 6 to 15 carbon atoms are preferred. In General formulae (II-1) and (II-2), R₃, R₄, and R₅, which may be the same or different, represent a single bond or a divalent aliphatic or aromatic hydrocarbon optionally substituted, preferably, for example, by an alkyl group, an aralkyl group, an aryl group, an alkoxy group, or a halogeno group. Among them, an alkylene group having 1 to 20 carbon atoms and an arylene group having 6 to 15 carbon atoms are preferred. More preferred is an alkylene group having 1 to 8 carbon atoms. If necessary, R₃, R₄, and R₅ may contain other functional group nonreactive with an isocyanate group, for example, any of a carbonyl group, an ester group, an urethane group, an amide group, an ureido group, and an ether group. Two or three of R₂, R₃, R₄, and R₅ together may form a ring. Ar represents an optionally substituted trivalent aromatic hydrocarbon, and an aromatic group having 6 to 15 carbon atoms is preferred.

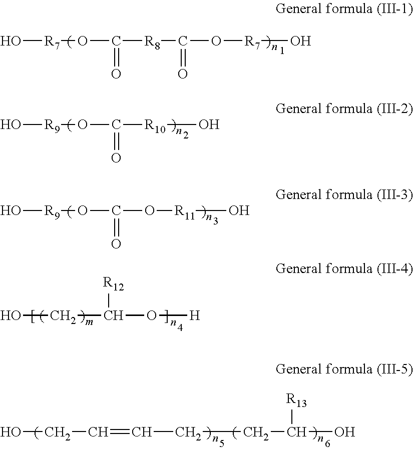

In formulae (III-1) to (III-3), R₇, R₈, R₉, R₁₀, and R₁₁, which may be the same or different, represent a divalent aliphatic or aromatic hydrocarbon. R₇, R₉, R₁₀, and R₁₁ each preferably represent an alkylene group having 2 to 20 carbon atoms or an arylene group having 6 to 15 carbon atoms, more preferably an alkylene group having 2 to 10 carbon atoms or an arylene group having 6 to 10 carbon atoms. R₈ represents an alkylene group having 1 to 20 carbon atoms or an arylene group having 6 to 15 carbon atoms, more preferably an alkylene group having 1 to 10 carbon atoms or an arylene group having 6 to 10 carbon atoms. R₇, R₈, R₉, R₁₀, and R₁₁ may contain a functional group nonreactive with an isocyanate group, for example, an ether group, a carbonyl group, an ester group, a cyano group, an olefin group, a urethane group, an amide group, or an ureido group, or a halogen atom.

In General formula (III-4), R₁₂ represents a hydrogen atom, an alkyl group, an aryl group, an aralkyl group, or a cyano group, or a halogen atom. R₁₂ preferably represents a hydrogen atom, an alkyl group having 1 to 10 carbon atoms, an aryl group having 6 to 15 carbon atoms, an aralkyl or cyano group having 7 to 15 carbon atoms, or a halogen atom, more preferably a hydrogen atom, an alkyl group having 1 to 6 carbon atoms, or an aryl group having 6 to 10 carbon atoms. R₁₂ may contain a functional group nonreactive with an isocyanate group, for example, an alkoxy group, a carbonyl group, an olefin group, or an ester group or a halogen atom.

In General formula (III-5), R₁₃ represents an aryl or cyano group, preferably an aryl or cyano group having 6 to 10 carbon atoms. In General formula (III-4), m is an integer of 2 to 4.

In General formulae (III-1) to (III-5), n₁, n₂, n₃, n₄, and n₅ each are an integer of 2 or more, preferably an integer of 2 to 100. In General formula (III-5), n6 is 0 or an integer of 2 or more, preferably 0 or an integer of 2 to 100.

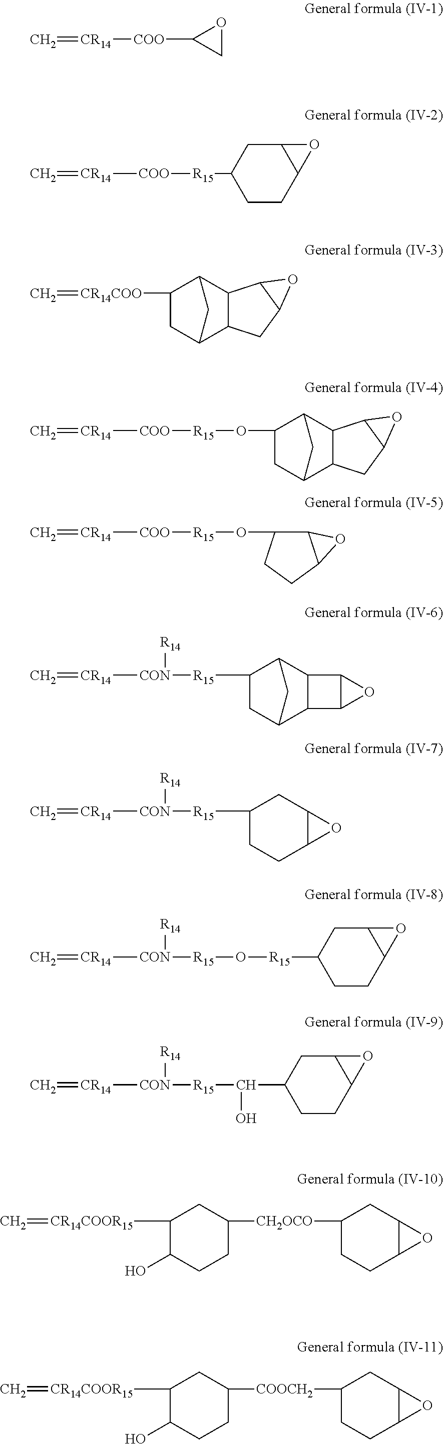

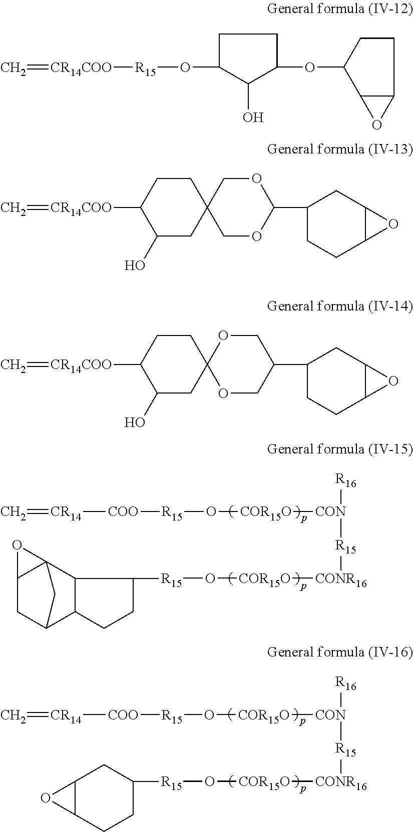

In General formulae (IV-1) to (IV-16), R₁₄ represents a hydrogen atom or a methyl group; R₁₅ represents an alkylene group having 1 to 10 carbon atoms; R₁₆ represents a hydrocarbon group having 1 to 10 carbon atoms; and p is 0 or an integer of 1 to 10.

The polyurethane resin may further be copolymerized with a carboxylic acid group-free low-molecular weight diol as a fifth ingredient. Diols represented by any of General formulae (III-1) to (III-5) and having a mass average molecular weight of 500 or less may be mentioned as the low-molecular weight diol. The carboxylic acid group-free low-molecular weight diol may be added in such an amount range that does not lower alkali solubility and, at the same time, can maintain the modulus of elasticity of the cured film satisfactorily low.

Suitable polyurethane resins are alkali-soluble photocrosslinkable polyurethane resins that have an acid value of 20 mgKOH/g to 120 mgKOH/g and are obtained by providing a reaction product between a diisocyanate represented by General formula (1) and at least one diol selected from carboxylic acid group-containing diols represented by any of General formulae (II-1) to (II-3) as indispensable ingredients and at least one diol selected from high-molecular weight diols represented by any of General formulae (III-1) to (III-5) and having a mass average molecular weight in the range of 800 to 3,000 and a carboxylic acid group-free low-molecular weight diols represented by any of General formulae (III-1) to (III-5) and having a mass average molecular weight of 500 or less according to contemplated purposes and further reacting the reaction product with a compound represented by any of General formulae (IV-1) to (IV-16) and having one epoxy and at least one (meth)acryl groups in a molecule thereof.

One type of these high-molecular weight compounds may be used, or alternatively two or more types of these high-molecular weight compounds may be used in combination.

### —Process for Synthesizing Polyurethane Resin Obtained by Reacting Carboxyl Group-Containing Polyurethane and Compound Having an Epoxy Group and a Vinyl Group in a Molecule Thereof—

The polyurethane resin may be synthesized by placing the diisocyanate compound and the diol compound(s) in an aprotic solvent, adding a conventional active catalyst depending upon the reactivity of the compounds, and heating the mixture. The molar ratio of the diisocyanate to the diol compound is preferably 0.8:1 to 1.2:1. When the isocyanate group remains at the end of the polymer, the treatment of the product with alcohols or amines can allow the polyurethane resin to be finally synthesized without residual isocyanate groups.

### ——Carboxylic Acid Group-Containing Diol——

The carboxyl-containing diol compound represented by any of General formulae (II-1) to (II-3) is not particularly limited and may be properly selected according to contemplated purposes. Examples thereof include compounds described in paragraph [0047] in JP-A No. 2007-2030.

### ——Carboxylic Acid Group-Free Low-Molecular Weight Diol——

The carboxylic acid group-free low-molecular weight diol is not particularly limited and may be properly selected according to contemplated purposes. Examples thereof include compounds described in paragraph [0048] in JP-A No. 2007-2030.

The amount of comonomer of the carboxylic acid group-free diol in the low-molecular weight diol is preferably 95% by mole or less, more preferably 80% by mole or less, particularly preferably 50% by mole or less. When the amount of the comonomer exceeds 95% by mole, a urethane resin having good developability cannot be sometimes obtained.

Specific examples of polyurethane resins obtained by reacting (ii) the carboxyl group-containing polyurethane with a compound having an epoxy group and a vinyl group in a molecule thereof include polymers obtained by replacing glycidyl acrylate as the epoxy group and vinyl group-containing compounds in polymers of U1 to U4 and U6 to U11 described in paragraphs [0314] and [0315] in JP-A No. 2007-2030 with glycidyl methacrylate, 3,4-epoxycyclohexyl methylacrylate (tradename: CYCLOMER A400, manufactured by Daicel Chemical Industries, Ltd.) and 3,4-epoxycyclohexylmethyl methacrylate (tradename: CYCLOMER M400, manufactured by Daicel Chemical Industries, Ltd.).

The content of the acid-modified vinyl group-containing polyurethane resin in the photosensitive composition is not particularly limited and may be properly selected according to contemplated purposes. The content of the acid-modified vinyl group-containing polyurethane resin is preferably 5% by mass to 80% by mass, more preferably 20% by mass to 75% by mass, particularly preferably 30% by mass to 70% by mass.

When the content of the acid-modified vinyl group-containing polyurethane resin is less than 5% by mass, good crack resistance cannot be sometimes maintained. On the other hand, when the content of the acid-modified vinyl group-containing polyurethane resin exceeds 80% by mass, the heat resistance can be spoiled. When the content of the acid-modified vinyl group-containing polyurethane resin is in the particularly preferred range, good crack resistance and heat resistance are advantageously simultaneously realized.

The mass average molecular weight of the acid-modified vinyl group-containing polyurethane resin is not particularly limited and may be properly selected according to contemplated purposes. The mass average molecular weight is preferably 5,000 to 60,000, more preferably 5,000 to 50,000, particularly preferably 5,000 to 30,000. When the mass average molecular weight is less than 5,000, a satisfactorily low modulus of elasticity cannot be sometimes obtained in the cured film at elevated temperatures. On the other hand, when the mass average molecular weight exceeds 60,000, the coatability and developability are sometimes deteriorated.

The mass average molecular weight may be measured with a high-performance gel permeation chromatography (GPC) (HLC-802A, manufactured by TOSOH Co., Ltd.). A 0.5% by mass THF solution is used as a sample solution. One column of TSKgel HZM-M is provided. The sample (200 μL) is injected and eluted with the THF solution, followed by measurement at 25° C. with a refractive index detector or a UV detector (detection wavelength: 254 nm). The mass average molecular weight was determined with a molecular weight distribution curve that had been calibrated using standard polystyrene.

The acid value of the acid-modified vinyl group-containing polyurethane resin is not particularly limited and may be properly selected according to contemplated purposes. The acid value is preferably 20 mgKOH/g to 120 mgKOH/g, more preferably 30 mgKOH/g to 110 mgKOH/g, particularly preferably 35 mgKOH/g to 100 mgKOH/g. When the acid value is less than 20 mgKOH/g, the developability is sometimes unsatisfactory. On the other hand, when the acid value exceeds 120 mgKOH/g, the development speed is so high that the regulation of the development becomes sometimes difficult.

The acid value may be measured, for example, according to JIS K 0070. When the sample does not melt, for example, dioxane or tetrahydrofuran is used as a solvent.

The vinyl group equivalent of the acid-modified vinyl group-containing polyurethane resin is not particularly limited and may be properly selected according to contemplated purposes. The vinyl group equivalent is preferably 0.05 mmol/g to 1.8 mmol/g, more preferably 0.5 mmol/g to 1.8 mmol/g, particularly preferably 0.75 mmol/g to 1.6 mmol/g. When the vinyl group equivalent is less than 0.05 mmol/g, the heat resistance of the cured film is sometimes poor. On the other hand, when the vinyl group equivalent exceeds 1.8 mmol/g, the crack resistance is sometimes deteriorated.

The vinyl group equivalent may be determined, for example, by measuring a bromine value. The bromine value may be measured, for example, according to JIS K 2605.

### <Phosphorus-Containing Flame Retardant>

The phosphorus-containing flame retardant is not particularly limited and may be properly selected according to the contemplated purposes. Examples thereof include a condensed phosphoric acid compound, a polyphosphoric acid melamine salt, a phosphazene compound, and a metal phosphate. One type of these phosphorus-containing flame retardants may be used, or alternatively, two or more types of these phosphorus-containing flame retardants may be used in combination.

Examples of the condensed phosphoric acid compound include resorcinol bis-diphenylphosphate, resorcinol bis-dixyleneylphosphate, and bisphenol A bis-diphenylphosphate. A commercially available product can be also used, and examples thereof include CR-733S, CR-741, CR-747, PX-200 (all manufactured by Daihachi Chemical Industry Co., Ltd.), FP-600, FP-700 (all manufactured by Adeka Corporation), REOFOS RDP, and REOFOS BAPP (all manufactured by Ajinomoto Fine-Techno Co., Inc.).

Examples of the polyphosphoric acid melamine salt include a compound represented by the following General formula. A commercially available product can be also used, and examples thereof include AP750, AP760, OP1312 (all manufactured by, Clariant (Japan) K.K.), FP-2100J, FP-2200 (all manufactured by, Adeka Corporation), HISHIGARD 6ME (manufactured by Nippon Chemical Industrial Co., Ltd.), and FCP-770 (manufactured by Suzuhiro Chemical Co., Ltd.).

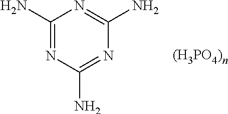

Examples of the phosphazene compound include a compound represented by the following General formula wherein R represents a hydrogen atom or an alkyl group having 1 to 8 carbon atoms. A commercially available product can be also used, and examples thereof include SPS-100 (manufactured by Otsuka Chemical Co., Ltd.).

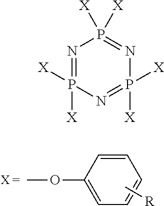

Examples of the metal phosphate include those represented by the following General formula wherein M represents at least one selected from Mg, Ca, Al, Sb, Sn, Ge, Ti, Zn, Fe, Zr, Ce, Bi, Sr, Mn, Ni, and Na; and m represents an integer of 1 to 4. A commercially available product can be also used, and examples thereof include OP-935 (manufactured by Clariant (Japan) K.K.).

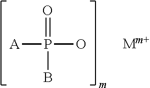

Content of the phosphorus-containing flame retardant in the solid contents of the photosensitive composition is preferably from 10% by mass to 35% by mass, and more preferably from 15% by mass to 25% by mass. When the content is less than 10% by mass, flame retardancy may not be maintained at sufficient level. On the other hand, when it is more than 35% by mass, the resolution and folding resistance may be deteriorated, and also insulation reliability may be deteriorated.

### <Polymerizable Compound>

The polymerizable compound is not particularly limited and may be properly selected according to contemplated purposes. Examples of preferred polymerizable compounds include compounds containing one or more ethylenically unsaturated bonds.

Examples of the ethylenically unsaturated bonds include vinyl groups such as (meth)acryloyl, (meth)acrylamide, styryl, vinyl ester, and vinyl ether; and allyl groups such as allyl ether and allyl ester.

The compound containing one or more ethylenically unsaturated bonds is not particularly limited and may be properly selected according to contemplated purposes. For example, at least one compound selected from (meth)acryl group-containing monomers is suitable.

The (meth)acryl group-containing monomer is not particularly limited and may be properly selected according to contemplated purposes. Examples thereof include monofunctional acrylates and monofunctional methacrylates such as polyethylene glycol mono(meth)acrylate, polypropylene glycol mono(meth)acrylate, and phenoxyethyl (meth)acrylate; compounds obtained by subjecting polyfunctional alcohols such as polyethylene glycol di(meth)acrylate, polypropylene glycol di(meth)acrylate, trimethylolethane triacrylate, trimethylolpropane triacrylate, trimethylolpropane diacrylate, neopentyl glycol di(meth)acrylate, pentaerythritol tetra(meth)acrylate, pentaerythritol tri(meth)acrylate, dipentaerythritol hexa(meth)acrylate, dipentaerythritol penta(meth)acrylate, hexanediol di(meth)acrylate, trimethylolpropane tri(acryloyloxypropyl)ether, tri(acryloyloxyethyl) isocyanurate, tri(acryloyloxyethyl) cyanurate, glycerin tri(meth)acrylate, trimethylolpropane, glycerin or bisphenol to an addition reaction with ethylene oxide or propylene oxide and then (meth)acrylating the addition production; urethane acryaltes described, for example, in Japanese Patent Application Publication (JP-B) Nos. 48-41708 and 50-6034, and JP-A No. 51-37193; polyester acrylates described, for example, in JP-A No. 48-64183, JP-B Nos. 49-43191, and 52-30490; and polyfunctional acrylates or methacrylates such as epoxyacrylates that are reaction products between epoxy resins and (meth)acrylic acids. One of these (meth) acryl group-containing monomers may be used, or alternatively, two or more types of these (meth)acryl group-containing monomers may be used in combination. Among them, trimethylolpropane tri(meth)acrylate, pentaerythritol tetra(meth)acrylate, dipentaerythritol hexa(meth)acrylate, and dipentaerythritol penta(meth)acrylate are particularly preferred.

The content of the polymerizable compound in the solid content of the photosensitive composition is preferably 5% by mass to 50% by mass, more preferably 10% by mass to 40% by mass. When the content is 5% by mass or more, the developability and the exposure sensitivity are good. On the other hand, when the solid content is 50% by mass or less, it is possible to prevent an enhancement of the tackiness of the photosensitive layer to an excessively high value.

### <Photopolymerization Initiator>

The photopolymerization initiator is not particularly limited as long as it has a capability of initiating the polymerization of the polymerizable compound. The photopolymerization initiator may be properly selected according to contemplated purposes. For example, photopolymerization initiators that are photosensitive upon exposure to light in a region from ultraviolet light to visible light are preferred. The photopolymerization initiators may be activators that generate active radicals through some action on a photoexcited sensitizer, or alternatively may be initiators that initiate cation polymerization depending upon the type of the monomer.

Preferably, the photopolymerization initiator contains at least one ingredient that has a molecular extinction coefficient of at least about 50 in a wavelength range of about 300 nm to about 800 nm. The wavelength is more preferably 330 nm to 500 nm.

A neutral photopolymerization initiator is used as the photopolymerization initiator. If necessary, the photopolymerization initiator may contain other photopolymerization initiators.

The neutral photopolymerization initiator is not particularly limited and may be properly selected according to contemplated purposes. Compounds containing at least an aromatic group are preferred. (Bis)acylphosphine oxides or esters thereof, acetophenone compounds, benzophenone compounds, benzoin ether compounds, ketal derivative compounds, and thioxanthone compounds are more preferred. One of these neutral photopolymerization initiators may be used, or alternatively, two or more types of these neutral photopolymerization initiators may be used in combination.

Examples of the photopolymerization initiators include (bis)acylphosphine oxides or esters thereof, acetophenone compounds, benzophenone compounds, benzoin ether compounds, ketal derivative compounds, thioxanthone compounds, oxime derivatives, organic peroxides, and thio compounds. Among them, oxime derivatives, (bis)acylphosphine oxides or esters thereof, acetophenone compounds, benzophenone compounds, benzoin ether compounds, ketal derivative compounds, and thioxanthone compounds are preferred, for example, from the viewpoints of the sensitivity of the photosensitive layer, the storage stability, and the adhesion between the photosensitive layer and the board for a printed wiring board.

Examples of the (bis)acylphosphine oxides include 2,6-dimethylbenzoyldiphenylphosphine oxide, 2,4,6-trimethylbenzoyldiphenylphosphine oxide, 2,4,6-trimethylbenzoylphenylphosphinic acid methyl ester, 2,6-dichlorobenzoylphenylphosphine oxide, 2,6-dimethyloxybenzoyldiphenylphosphine oxide, bis(2,6-dimethyloxybenzoyl)-2,4,4-trimethyl-pentylphosphine oxide, and bis(2,4,6-trimethylbenzoyl)-phenylphosphine oxide.

Examples of the acetophenone compounds include acetophenone, methoxyacetophenone, 1-phenyl-2-hydroxy-2-methylpropan-1-one, 1-hydroxycyclohexyl phenyl ketone, 4-diphenoxydichloroacetophenone, diethoxyacetophenone, and 1-(4-isopropylphenyl)-2-hydroxy-2-methylpropan-1-one.

Examples of the benzophenone compounds include benzophenone, 4-phenylbenzophenone, methyl benzoylbenzoate, 4-phenylbenzophenone, hydroxybenzophenone, 3,3′-dimethyl-4-methoxybenzophenone, and diphenoxybenzophenone.

Examples of the benzoin ether compounds include benzoin ethyl ether and benzoin propyl ether.

Examples of the ketal derivative compounds include benzyl dimethyl ketal.

Examples of the thioxanthone compounds include 2-chlorothioxanthone, 2,4-dimethylthioxanthone, 2,4-diethylthioxanthone, 2,4-diisopropylthioxanthone, and isopropylthioxanthone.

Examples of oxime derivatives suitable in the present invention include compounds represented by General formula (1).

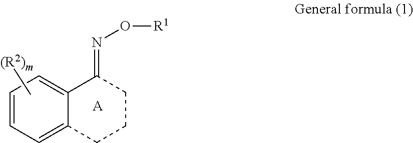

In General formula (1), R¹ represents any of a hydrogen atom and optionally substituted acyl, alkoxycarbonyl, aryloxycarbonyl, alkylsulfonyl, and aryl sulfonyl groups; R²s each independently represent a substituent; m is an integer of 0 to 4, provided that, when m is 2 or more, they may be mutually connected to form a ring; and A represents any of four-, five-, six-, and seven-membered rings with any of five- and six-membered rings being preferred.

Examples of oxime derivatives (oxime compounds) used in the present invention are more preferably compounds represented by General formula (2).

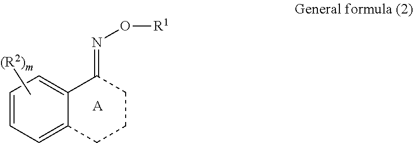

In General formula (2), R¹ represents any of a hydrogen atom and optionally substituted acyl, alkoxycarbonyl, aryloxycarbonyl, alkylsulfonyl, and arylsulfonyl groups; R²s each independently represent a substituent; m is an integer of 0 to 4, provided that, when m is 2 or more, they may be mutually connected to form a ring; X represents CH₂, O, or S; and A represents any of five- and six-membered rings.

The acyl group represented by R¹ in the General formulae (1) and (2) may be an aliphatic group, an aromatic group, or a heterocyclic group; and optionally further substituted.

Examples of the aliphatic group include acetyl, propanoyl, butanoyl, hexanoyl, decanoyl, phenoxyacetyl, and chloroacetyl. Examples of the aromatic group include benzoyl, naphthoyl, methoxybenzoyl, and nitrobenzoyl. Examples of the heterocyclic group include furanoyl, and thiophenoyl.

The substituent is preferably, for example, an alkoxy group, an aryloxy group or a halogen atom.

The acyl group has preferably 2 to 30 carbon atoms in total, more preferably 2 to 20 carbon atoms in total, particularly preferably 2 to 16 carbon atoms in total.

Examples of the acyl group include acetyl, propanoyl, methylpropanoyl, butanoyl, pivaloyl, hexanoyl, cyclohexanecarbonyl, octanoyl, decanoyl, dodecanoyl, octadecanoyl, benzylcarbonyl, phenoxyacetyl, 2-ethylhexanoyl, chloroacetyl, benzoyl, paramethoxybenzoyl, 2,5-dibutoxybenzoyl, 1-naphthoyl, 2-naphthoyl, pyridylcarbonyl, methacryloyl and acryloyl.

The alkyloxycarbonyl group is optionally substituted, and is preferably an alkoxycarbonyl group having 2 to 30 carbon atoms in total, more preferably 2 to 20 carbon atoms in total, particularly preferably 2 to 16 carbon atoms in total. Examples of the alkoxycarbonyl group include methoxycarbonyl, ethoxycarbonyl, isopropoxycarbonyl, butoxylcarbonyl, isobutyloxycarbonyl, allyloxycarbonyl, octyloxycarbonyl, dodecyoxycarbonyl and ethoxyethoxycarbonyl.

The aryloxylcarbonyl group is optionally substituted, and is preferably an alkoxycarbonyl group having 7 to 30 carbon atoms in total, more preferably 7 to 20 carbon atoms in total, particularly preferably 7 to 16 carbon atoms in total. Examples of the aryloxylcarbonyl group include phenoxycarbonyl, 2-naphthoxycarbonyl, paramethoxyphenoxycarbonyl, 2,5-diethoxyphenoxycarbonyl, parachlorophenoxycarbonyl, paranitrophenoxycarbonyl and paracyanophenoxycarbonyl.

The alkylsulfonyl group is optionally further substituted. The alkylsulfonyl group is preferably substituted with a phenyl group, a halogen atom, an alkoxy group, an aryloxy group, an alkoxycarbonyl group, an acyloxy group, an acylamino group, a carbamoyl group, a cyano group, a carboxylic acid group, a sulphonic acid group, or a heterocyclic group. Particularly preferably examples of the alkylsulfonyl group include methylsulfonyl, butylsulfonyl, octylsulfonyl, decylsulfonyl, dodecylsulfonyl, benzylsulfonyl, and trifloromethylsulfonyl.

The arylsulfonyl group is optionally further substituted. The arylsulfonyl group is preferably substituted with a phenyl group, a halogen atom, an alkoxy group, an aryloxy group, an alkoxycarbonyl group, an acyloxy group, an acylamino group, a carbamoyl group, a cyano group, a carboxylic acid group, a sulphonic acid group, or a heterocyclic group. Particularly preferably examples of the arylsulfonyl group include benzenesulfonyl, toluenesulfonyl, chlorobenzenesulfonyl, butoxybenzenesulfonyl, 2,5-dibutoxybenzenesulfonyl, paranitrobenzenesulfonyl, and perfluorobenzenesulfonyl.

The substituent represented by R² in the General formulae (1) and (2) includes aliphatic, aromatic, heteroaromatic, a halogen atom, —OR³, —SR³ and —NR³R⁴. R³ and R⁴ may be linked together to form a ring. R³ and R⁴ each independently represent a hydrogen atom, an aliphatic group, an aromatic group or a heteroaromatic group. When m is 2 or more and R²s are linked together to form a ring, independently selected R²s may be directly linked to together to form a ring, or may be linked together via R³ and/or R⁴ to form a ring. When a ring is formed via R², the resultant ring includes those have the following structures:

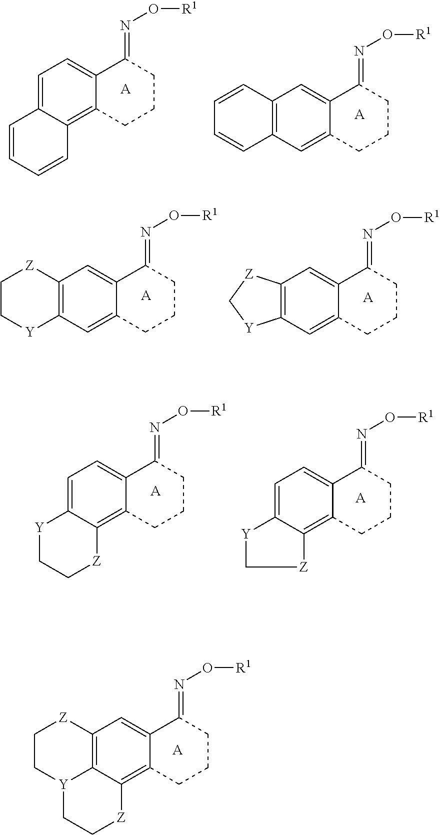

In the above Structural Formulae, Y and Z each represent CH₂, —O—, —S— or —NR—.

Specific examples of the aliphatic, aromatic or heteroaromatic group represented by R², R³ or R⁴ include those listed above in relation to R¹.

Examples of the oxime compound represented by General formula (1) include compounds represented by the following Structural Formulae (1) to (51), which should not be construed as limiting the present invention thereto.

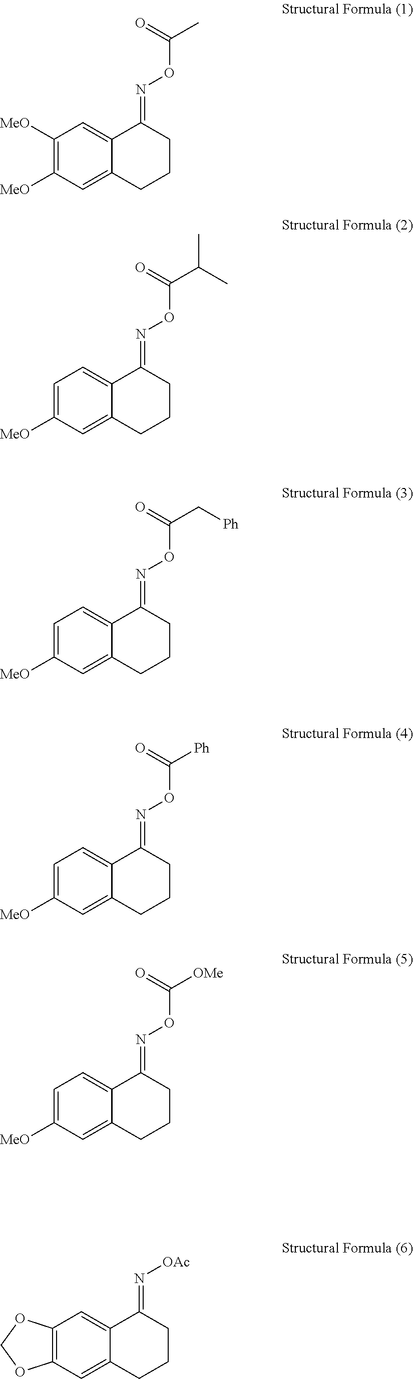

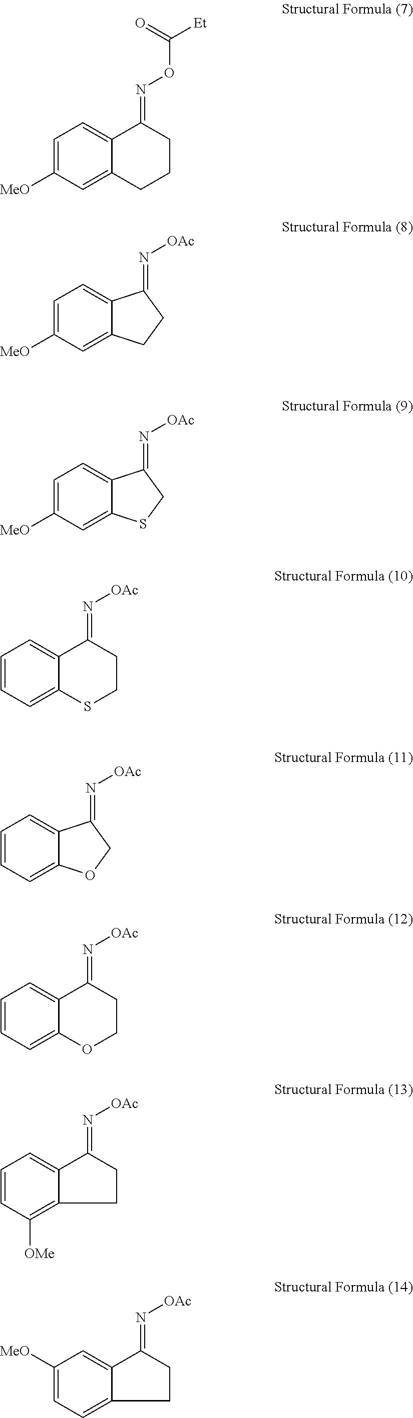

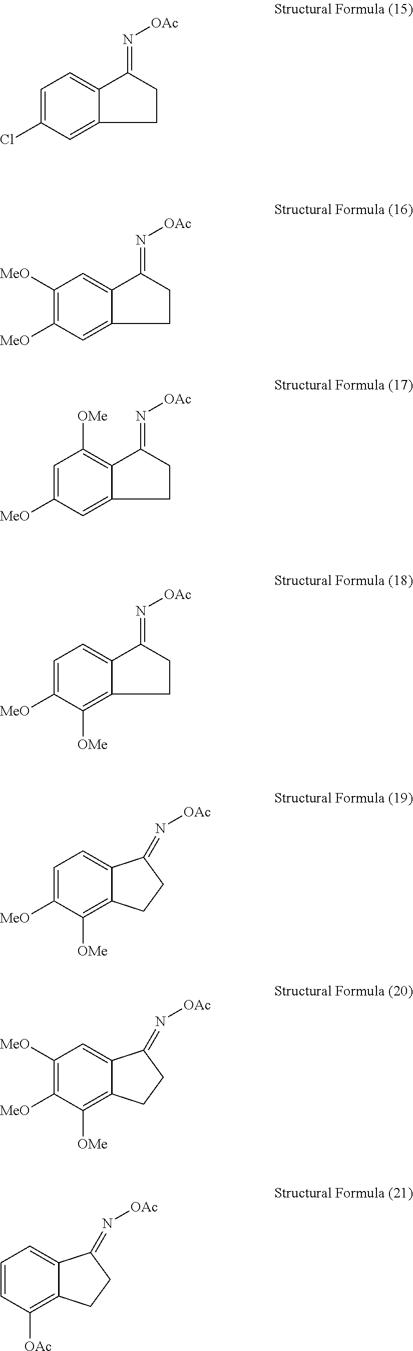

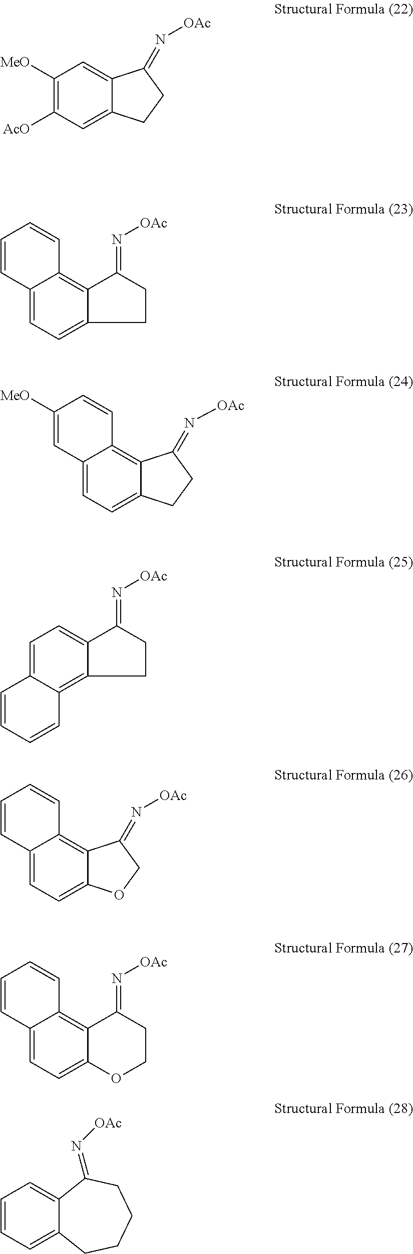

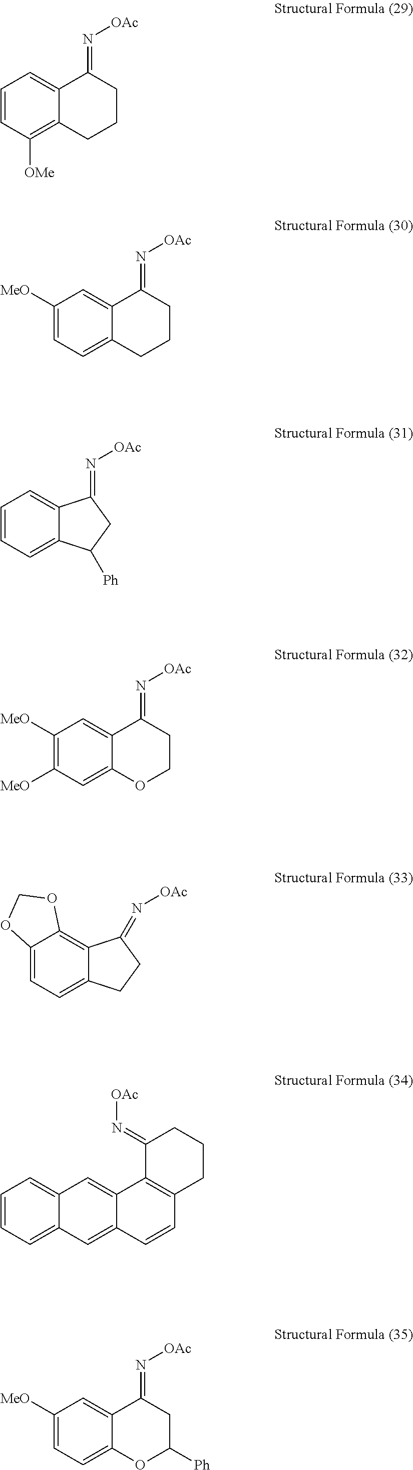

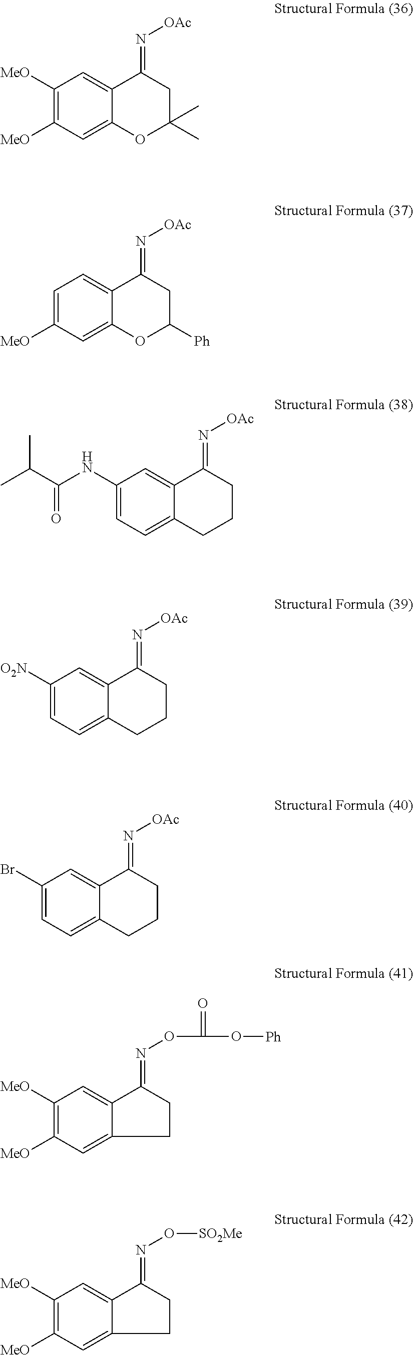

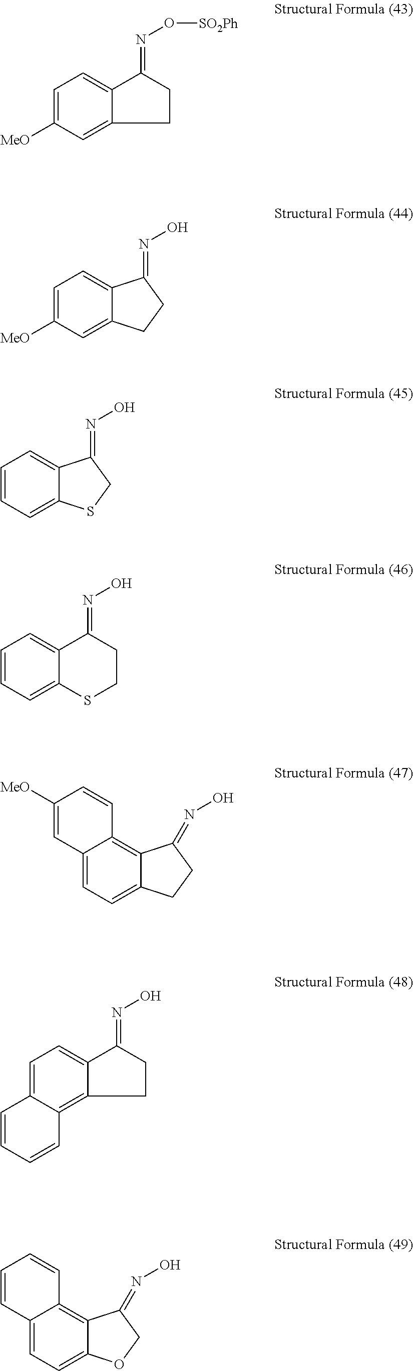

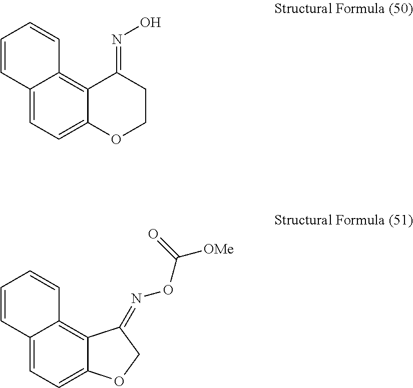

Notably, oxime compounds used in the present invention can be identified through ¹H-NMR spectral analysis or UV-vis absorption spectral analysis.

The oxime compounds can be easily synthesized by reacting an oxime compound corresponding thereto (hereinafter referred as a “starting oxime compound”) with acyl chloride or anhydride in the presence of a base (e.g., triethylamine or pyridine) in an inert solvent (e.g., THF, DMF or acetonitrile) or a basic solvent (e.g., pyridine). The reaction temperature is preferably −10° C. to 60° C.

Also, when chloroformic acid ester, alkylsulfonyl chloride or arylsulfonyl chloride are used as the acyl chloride, corresponding various oxime ester compounds can be synthesized.

The starting oxime compound used for the production of the oxime compound as a starting material can be synthesized by a variety of methods described in standard chemistry textbooks (e.g., J. March, Advanced Organic Chemistry, 4th Edition, Wiley Interscience, 1992), or in specialized monographs such as S. R. Sandler & W. Karo, Organic functional group preparations, Vol. 3, Academic Press.

Particularly preferably, the starting oxime compound can be synthesized by reacting aldehydes or ketones with hydroxylamine or its salt in polar solvents such as ethanol or aqueous ethanol. In that case, a base such as sodium acetate or pyridine is added to control the pH of the reaction mixture. It is well known that the rate of the reaction is pH-dependent, and the base can be added at the beginning or continuously during the reaction. Basic solvents such as pyridine can also be used as base and/or solvent or cosolvent. The reaction temperature is generally the refluxing temperature of the mixture, namely, is preferably 60° C. to 120° C.

Another preferable synthesis method of the starting oxime compound is the nitrosation of an “active” methylene group with nitrous acid or an alkyl nitrite. Both alkaline conditions, as described, for example, in Organic Syntheses coll. Vol. VI (J. Wiley & Sons, New York, 1988), pp. 199 and 840, and acidic conditions, as described, for example, in Organic Synthesis coll. Vol. V, pp. 32 and 373, coll. Vol. III, pp. 191 and 513, coll. Vol. II pp. 202, 204 and 363, are suitable for the synthesis of the starting oxime compound.

Nitrous acid is usually generated from sodium nitrite.

Examples of the alkyl nitrite include methyl nitrite, ethyl nitrite, isopropyl nitrite, butyl nitrite, and isoamyl nitrite.

The group of the oxime ester can exist in any of two types of steric configurations, (Z) or (E). The isomers thereof may be separated by conventional methods, or the isomeric mixture may be used as photoinitiating species as is. Therefore, the oxime compound may be a mixture of configurational isomers of compounds of Structural Formulae (1) to (51).

The oxime compound is excellent in storage stability and sensitivity. Thus, a polymerizable composition containing the oxime compound can be excellent in storage stability in that the polymerizable compound does not polymerize during storage, and can be highly sensitive in that the oxime compound efficiently initiates the polymerization of the polymerizable compound by generating active radicals upon irradiation of energy beam, especially light, to thereby allow the polymerizable compound to be quickly and efficiently polymerized.

One of these photopolymerization initiators may be used, or alternatively, two or more types of these photopolymerization initiators may be used in combination.

The content of the photopolymerization initiator in the solid content of the photosensitive composition is preferably 0.1% by mass to 30% by mass, more preferably 0.5% by mass to 20% by mass, particularly preferably 0.5% by mass to 15% by mass.

### <Thermal Crosslinking Agent>

The thermal crosslinking agent is not particularly limited and may be properly selected according to contemplated purposes. In order to improve the film strength after curing of the photosensitive layer formed using the photosensitive film, for example, compounds containing epoxy compounds such as epoxy compounds having at least two oxirane groups in one molecule, and oxetane compounds having at least two oxetanyl groups in one molecule can be used in such an amount that the developability is not adversely affected. Examples thereof include epoxy compounds having an oxirane group as described in JP-A No. 2007-47729, epoxy compounds having an alkyl group at the β position, oxetane compounds having an oxetanyl group, polyisocyanate compounds, and compounds obtained by reacting an isocyanate group in a polyisocyanate and other derivatives with a blocking agent.

Melamine derivatives may be used as the thermal crosslinking agent. Examples of the melamine derivatives include methylol melamines and alkylated methylol melamines (compounds obtained by etherificating a methylol group with, for example, methyl, ethyl, or butyl). One of these melamine derivatives may be used, or alternatively, two or more types of these melamine derivatives may be used in combination. Among them, alkylated methylol melamines are preferred, and hexamethylated methylol melamines are particularly preferred from the viewpoint of realizing good storage stability and effectively improving the surface hardness of the photosensitive layer or the film strength per se of the cured film.

The content of the thermal crosslinking agent in the solid content of the photosensitive composition is preferably 1% by mass to 50% by mass, more preferably 3% by mass to 30% by mass. When the content is 1% by mass or more, the film strength of the cured film is improved. On the other hand, when the solid content is 50% by mass or less, the developability and exposure sensitivity are good.

Examples of the epoxy compounds include epoxy compounds having at least two oxirane groups in one molecule and epoxy compounds containing at least two epoxy groups having an alkyl group at the f3 position in one molecule.

Examples of the epoxy compounds having at least two oxirane groups in one molecule include, but are not limited to, bixylenol or biphenol epoxy resins (for example, “YX4000, manufactured by Japan Epoxy Resin Co., Ltd.”) or their mixtures, heterocyclic epoxy resins having, for example, an isocyanurate skeleton (for example, “TEPIC; manufactured by Nissan Chemical Industries Ltd.,” and “ARALDITE PT810; manufactured by Ciba Specialty Chemicals, K.K.”), bisphenol A epoxy resins, novolak epoxy resins, bisphenol F epoxy resins, hydrogenated bisphenol A epoxy resins, bisphenol S epoxy resins, phenol novolak epoxy resins, cresol novolak epoxy resins, halogenated epoxy resins (for example, low brominated epoxy resins, high halogenated epoxy resins, brominated phenol novolak epoxy resins), aryl group-containing bisphenol A epoxy resins, trisphenolmethane epoxy resins, diphenyl dimethanol epoxy resins, phenol-biphenylene epoxy resins, dicyclopentadiene epoxy resins (for example, “HP-7200 and HP-7200H; manufactured by Dainippon Ink and Chemicals, Inc.”), glycidylamine epoxy resins (for example, diaminodiphenylmethane epoxy resins, diglycidylaniline, and triglycidyl aminophenol), glycidyl ester epoxy resins (for example, phthalic acid diglycidyl ester, adipic acid diglycidyl ester, hexahydrophthalic acid diglycidyl ester, and dimer acid diglycidyl ester), hydantoin epoxy resins, alicyclic epoxy resins (3,4-epoxycyclohexylmethyl-3′,4′-epoxycyclohexane carboxylate, bis(3,4-epoxycyclohexylmethyl)adipate, dicyclopentadienediepoxide (for example, “GT-300, GT-400, and ZEHPE3150; manufactured by Daicel Chemical Industries, Ltd.”), imide alicyclic epoxy resins, trihydroxyphenylmethane epoxy resins, bisphenol A novolak epoxy resins, tetraphenylolethane epoxy resins, glycidyl phthalate resins, tetraglycidyl xylenoylethane resins, naphthalene group-containing epoxy resins (naphtholaralkyl epoxy resins, naphthol novolak epoxy resins, tetrafunctional naphthalene epoxy resins, commercially available products, for example, “ESN-190 and ESN-360; manufactured by Nippon Steel Chemical Co., Ltd.” and “HP-4032, EXA-4750, and EXA-4700; manufactured by Dainippon Ink and Chemicals, Inc.,” reaction products of epichlorohydrin with polyphenol compounds obtained by subjecting phenol compounds to an addition reaction with diolefin compounds such as divinylbenzene or dicyclopentadiene, compounds obtained by epoxidizing an ring-opening polymerization product of 4-vinylcyclohexene-1-oxide with, for example, peracetic acid, epoxy resins having a linear phosphorus-containing structure, epoxy resins having a cyclic phosphorus-containing structure, α-methylstilbene liquid crystal epoxy resins, dibenzoyloxybenzene liquid crystal epoxy resins, azophenyl liquid crystal epoxy resins, azomethine phenyl liquid crystal epoxy resins, binaphthyl liquid crystal epoxy resins, azine epoxy resins, glycidyl methacrylate copolymerized epoxy resins (for example, “CP-50S and CP-50M; manufactured by Nippon Oils & Fats Co., Ltd.”), cyclohexyl maleimide/glycidyl methacrylate copolymerized epoxy resins, bis(glycidyl oxyphenyl)fluorene epoxy resins, and bis(glycidyl oxyphenyl)adamantane epoxy resins. One type of these epoxy resins may be used, or alternatively, two or more types of these epoxy resins may be used in combination.

Further, in addition to the epoxy compounds having at least two oxirane groups in one molecule, epoxy compounds containing at least two epoxy groups having an alkyl group at the β position in one molecule may be used. Compounds containing an epoxy group substituted at the β position by an alkyl group (more specifically, β-alkyl-substituted glycidyl group) are particularly preferred.

The epoxy compounds containing at least an epoxy group having an alkyl group at the β position may be epoxy compounds in which all of two or more epoxy groups contained in one molecule are a β-alkyl-substituted glycicyl group or epoxy compounds in which at least one epoxy group is a β-alkyl-substituted glycidyl group.

Examples of the oxetane compounds include oxetane compounds having at least two oxetanyl groups in one molecule.

Specific examples thereof include polyfunctional oxetanes such as bis[(3-methyl-3-oxetanylmethoxy)methyl]ether, bis[(3-ethyl-3-oxetanylmethoxy)methyl]ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methyl acrylate, (3-ethyl-3-oxetanyl)methyl acrylate, (3-methyl-3-oxetanyl)methyl methacrylate, and (3-ethyl-3-oxetanyl)methyl methacrylate or oligomers or copolymers thereof. Other examples thereof include ether compounds between oxetane group-containing compounds and hydroxyl-containing resins such as novolak resins, poly(p-hydroxystyrene), cardo bisphenols, calixarenes, calixresorcinarenes, and silsesquioxane. Additional examples thereof include copolymers between oxetane ring-containing unsaturated monomers and alkyl (meth)acrylate s.

Polyisocyanate compounds described in JP-A No. 05-9407 may be used as the polyisocyanate compound. The polyisocyanate compounds may be derived from aliphatic group-, cycloaliphatic group- or aromatic group-substituted aliphatic compounds containing at least two isocyanate groups. Specific examples thereof include bifunctional isocyanates (for example, a mixture of 1,3-phenylene diisocyanate with 1,4-phenylene diisocyanate, 2,4- and 2,6-toluene diisocyanates, 1,3- and 1,4-xylylene diisocyanates, bis(4-isocyanate-phenyl)methane, bis(4-isocyanate-cyclohexyl)methane, isophorone diisocyanate, hexamethylene diisocyanate, and trimethylhexamethylene diisocyanate), polyfunctional alcohols between the bifunctional isocyanate and trimethylolpropane, pentaerythritol or glycerine; and adducts between the alkylene oxide adducts of the polyfunctional alcohols and the bifunctional isocyanates; and cyclic trimers such as hexamethylene diisocyanate, hexamethylene-1,6-diisocyanate, and derivatives thereof.

Isocyanate blocking agents in compounds obtained by reacting the polyisocyanate compound with a blocking agent, that is, compounds obtained by reacting an isocyanate group in a polyisocyanate and its derivative with a blocking agent include alcohols (for example, isopropanol and tert-butanol), lactams (for example, ε-caprolactam), phenols (for example, phenol, cresol, p-tert-butyl phenol, p-sec-butyl phenol, p-sec-amyl phenol, p-octyl phenol, and p-nonyl phenol), heterocyclic hydroxyl compounds (for example, 3-hydroxypyridine, and 8-hydroxyquinoline), and active methylene compounds (for example, dialkyl malonate, methyl ethyl ketoxime, acetyl acetone, alkyl acetoacetate oxime, acetoxime, and cyclohexanone oxime). Examples of additional compounds usable herein include compounds having any of at least one polymerizable double bond and at least one block isocyanate group in a molecule thereof as described in JP-A No. 06-295060.

Examples of melamine derivatives include methylol melamine and alkylated methylol melamines (compound obtained by etherificating a methylol group with, for example, methyl, ethyl, or butyl). One type of these melamine derivatives may be used, or alternatively, two or more types of melamine derivatives may be used in combination. From the viewpoints of realizing good storage stability and effectively improving the surface hardness of the photosensitive layer or the film strength per se of the cured film, among them, alkylated methylol melamines are preferred, and hexamethylated methylol melamine is particularly preferred.

### <Other Ingredients>

The other ingredients are not particularly limited and may be properly selected according to contemplated purposes. Examples thereof include fillers, thermal curing accelerators, thermal polymerization inhibitors, plasticizers, and colorants (coloring pigments or dyes). Further, the ingredients may be used in combination with adhesion promoters to the surface of base materials and other auxiliaries (for example, electroconductive particles, fillers, antifoaming agents, flame retardants, levelling agents, peeling promoters, antioxidants, perfumes, surface tension regulating agents, and chain transfer agents).

Properties such as stability, photographic properties, and film physical properties are regulated as contemplated photosensitive film by properly incorporating these ingredients.

The filler is described in detail, for example, in paragraphs [0098] and [0099] in JP-A No. 2008-250074.

The thermal polymerization inhibitor is described in detail, for example, in paragraphs [0101] and [0102] in JP-A No. 2008-250074.

The thermal curing accelerator is described in detail, for example, in paragraph [0093] in JP-A No. 2008-250074.

The plasticizer is described in detail, for example, in paragraphs [0103] and [0104] in JP-A No. 2008-250074.

The colorant is described in detail, for example, in paragraphs [0105] and [0106] in JP-A No. 2008-250074.

The adhesion promoter is described in detail, for example, in paragraphs [0107] to [0109] in JP-A No. 2008-250074.

### (Photosensitive Film)

The photosensitive film according to the present invention includes at least a support and a photosensitive layer that is provided on the support and is formed of the photosensitive composition according to the present invention. The photosensitive film may further include additional other layers according to need.

### —Support—

The support is not particularly limited and may be properly selected according to contemplated purposes. Preferably, the support can allow the photosensitive layer to be separated therefrom and is highly permeable to light. More preferably, the support further has good surface smoothness.

The support is preferably formed of a synthetic resin and is transparent. Examples thereof include various plastic films of polyethylene terephthalate, polyethylene naphthalate, polypropylene, polyethylene, cellulose triacetate, cellulose diacetate, poly(meth)acrylic acid alkyl ester, poly(meth)acrylic acid ester copolymers, polyvinyl chloride, polyvinyl alcohol, polycarbonates, polystyrene, cellophane, polyvinylidene chloride copolymers, polyamides, polyimides, vinyl chloride/vinyl acetate copolymers, polytetrafluoroethylene, polytrifluoroethylene, cellulosic films, and nylon films. Among them polyethylene terephthalate films are particularly preferred. One type of these films may be used, or alternatively, two or more types of these films may be used in combination.

The thickness of the support is not particularly limited and may be properly selected according to contemplated purposes. The thickness of the support is preferably 2 μm to 150 μm, more preferably 5 μm to 100 μm, particularly preferably 8 μm to 50 μm.

The shape of the support is not particularly limited and may be properly selected according to contemplated purposes. The support, however, is preferably elongated. The length of the elongated support is not particularly limited. For example, the length of the elongated support is 10 m to 20,000 m.

### —Photosensitive Layer—

The photosensitive layer is not particularly limited and may be properly selected according to contemplated purposes, as long as the photosensitive layer is formed of the photosensitive composition.

The number of photosensitive layers laminated is not particularly limited and may be properly selected according to contemplated purposes. For example, the photosensitive layer may have a single-layer structure or alternatively may have a multilayer structure of two or more layers.

The photosensitive layer may be formed by a method that includes dissolving, emulsifying, or dispersing the photosensitive composition according to the present invention in water or a solvent to prepare a photosensitive composition solution, coating the photosensitive composition solution onto the support directly, and drying the coating to laminate the layer.

The solvent for the photosensitive composition solution is not particularly limited and may be properly selected according to contemplated purposes. Examples thereof include alcohols such as methanol, ethanol, n-propanol, iso-propanol, n-butanol, sec-butanol, and n-hexanol; ketones such as acetone, methyl ethyl ketone, methyl isobutyl ketone, cyclohexanone, and diisobutyl ketone; esters such as ethyl acetate, butyl acetate, n-amyl acetate, methyl sulfate, ethyl propionate, dimethyl phthalate, ethyl benzoate, and methoxypropyl acetate; aromatic hydrocarbons such as toluene, xylene, benzene, and ethylbenzene; halogenated hydrocarbons such as carbon tetrachloride, trichloroethylene, chloroform, 1,1,1-trichloroethane, methylene chloride, and monochlorobenzene; ethers such as tetrahydrofuran, diethyl ether, ethylene glycol monomethyl ether, ethylene glycol monoethyl ether, and 1-methoxy-2-propanol; and dimethylformamide, dimethylacetamide, dimethylsulfo oxide, and sulfolane. One type of solvent may be used, or alternatively, two or more types of solvent may be used in combination. Further, conventional surfactants may be added.

The method for coating the photosensitive composition solution is not particularly limited and may be properly selected according to contemplated purposes. Examples thereof include a method including directly coating the composition solution onto the support, for example, using a spin coater, a slit spin coater, a roll coater, a die coater, or a curtain coater.

Conditions for drying may vary depending upon, for example, ingredients, the type of solvents, mixing ratios. In general, however, the drying is carried out at a temperature of 60° C. to 110° C. for about 30 sec to about 15 min.

The thickness of the photosensitive layer is not particularly limited and may be properly selected according to contemplated purposes. For example, however, the thickness of the photosensitive layer is preferably 1 μm to 100 μm, more preferably 2 μm to 50 μm, particularly preferably 4 μm to 30 μm.

### <<Other Layers>>

Other layers may be provided without particular limitation and may be properly selected according to contemplated purposes. Examples thereof include protective films, thermoplastic resin layers, barrier layers, peel layers, adhesion layers, light absorbing layers, and surface protective layers. The photosensitive film may have one type of these layers or two or more types of these layers.

### <<Protective Film>>

In the photosensitive film, a protective film may be formed on the photosensitive layer.

Examples of the protective films include films as used in the support, papers, and papers laminated with polyethylene or polypropylene. Among them, polyethylene and polypropylene films are preferred.

The thickness of the protective film is not particularly limited and may be properly selected according to contemplated purposes. For example, the thickness of the protective film is preferably 5 μm to 100 μm, more preferably 8 μm to 50 μm, particularly preferably 10 μm to 30 μm.

Examples of the combination of the support and the protective film (support/protective film) include polyethylene terephthalate/polypropylene, polyethylene terephthalate/polyethylene, polyvinyl chloride/cellophane, polyimide/polypropylene, and polyethylene terephthalate/polyethylene terephthalate. The interlayer adhesion can be regulated by surface-treating at least one of the support and the protective film. The surface of the support may be treated to enhance the adhesion of the support to the photosensitive layer. Examples of surface treatment methods include the provision of undercoating layer, corona discharge treatment, flame treatment, ultraviolet irradiation treatment, high frequency irradiation treatment, glow discharge irradiation treatment, active plasma irradiation treatment, and laser beam irradiation treatment.

The coefficient of static friction between the support and the protective film is preferably 0.3 to 1.4, more preferably 0.5 to 1.2.

When the coefficient of static friction is 0.3 or more, it is possible to prevent uneven winding in a roll form due to too slippery properties. When the coefficient of static friction is 1.4 or less, winding to a good roll state is possible.

Preferably, the photoselective film is wound around a cylindrical winding core and is stored in a continuous roll form. The length of the continuous photoselective film is not particularly limited and may be properly selected, for example, from a range of 10 m to 20,000 m. Further, a method may be adopted in which the photoselective film is slit so that the user can easily handle the photoselective film, and the continuous slit photosensitive film of 100 m to 1,000 m in length is wound as a roll. In this case, preferably, the photoselective film is wound so that the support is located on the outermost side. The roll of the photoselective film may be slit to sheets. In storing the photoselective film, from the viewpoints of protecting the end face and preventing edge fusion, a separator (particularly a moisture-proof or desiccant-containing separator) is preferably provided at the end face. Further, the use of a material having low permeability to moisture is preferred for packing.

The surface of the protective film may be treated to regulate the adhesion between the protective film and the photoselective layer. The surface treatment may be carried out by forming an undercoating layer formed of polymers such as polyorganosiloxane, fluorinated polyolefin, polyfluoroethylene, or polyvinyl alcohol on the surface of the protective film. The undercoating layer may be formed by coating a coating liquid of the polymer on the surface of the protective film and then drying the coating at 30° C. to 150° C. for 1 min to 30 min. The drying temperature is particularly preferably 50° C. to 120° C.

### (Photoselective Laminate)

The photoselective laminate includes at least a substrate and a photoselective layer provided on the substrate. Other layers that are properly selected according to purposes are laminated thereon.

The photoselective layer is one transferred from the photoselective film prepared by the above process and has the same construction as described above.

### <Substrate>

The substrate serves as a substrate on which a photoselective layer is to be formed, or a transfer target on which at least a photoselective layer in the photoselective film according to the present invention is transferred. The substrate is not particularly limited and may be properly selected according to contemplated purposes. For example, any substrate may be selected from substrates having a high surface smoothness to substrates having a concave and convex surface. The substrate is preferably in a plate form, that is, a board is used. Specifically, examples of substrates include conventional boards for printed wiring board production (printed boards), glass plates (for example, soda glass plates), synthetic resin films, papers, and metal plates.

### <Process for Producing Photoselective Laminate>

The photoselective laminate may be produced by transferring and laminating at least a photoselective layer in the photoselective film according to the present invention while performing at least one of heating and pressing.

The photoselective laminate is produced by laminating the photoselective film according to the present invention on the surface of the substrate while performing at least one of heating and pressing. When the photoselective film includes the protective film, the protective film is peeled off and the photoselective layer is then preferably laminated on the substrate so that the photoselective layer is superimposed on the substrate.

The heating temperature is not particularly limited and may be properly selected according to contemplated purposes. For example, the heating temperature is preferably 15° C. to 180° C., more preferably 60° C. to 140° C.

The pressure applied for pressing is not particularly limited and may be properly selected according to contemplated purposes. For example, the pressure is preferably 0.1 MPa to 1.0 MPa, more preferably 0.2 MPa to 0.8 MPa.

At least one of the heating may be carried out by any apparatus without particular limitation. The apparatus may be properly selected according to contemplated purposes. Examples of suitable apparatuses include laminators (for example, VP-II manufactured by TAISEI LAMINATOR CO,. LTD. and VP130 manufactured by Nichigo-Morton Co., Ltd.).

The photoselective film and the photoselective laminate according to the present invention have an even film thickness and hardly have surface defects such as pinholes or cissing and thus can efficiently form permanent patterns (for example, protective films, interlayer insulating films, and solder resist patterns) having excellent insulating reliability and high definition. Accordingly, the photoselective film and the photoselective laminate according to the present invention can be extensively used for the formation of highly definite permanent patterns in the field of electronic materials and are particularly suitable for the formation of permanent patterns in printed boards.

### (Method for Forming a Permanent Pattern)

The method for forming a permanent pattern according to the present invention includes at least an exposure step and further properly selected optional other steps such as a development step.

### <Exposure Step>

In the exposure step, the photoselective layer in the photoselective laminate according to the present invention is exposed to light. The photoselective laminate according to the present invention is as described above.

Any object may be exposed to light without particular limitation and may be properly selected according to contemplated purposes, as long as the object is a photoselective layer in the photoselective laminate. For example, preferably, a laminate formed by laminating a photoselective film on a base material while performing at least one of heating and pressing is exposed to light.

The exposure is not particularly limited and may be properly selected according to contemplated purposes. Examples thereof include digital exposure and analog exposure. Among them, digital exposure is preferred.

### <Other Steps>

Other steps may be provided without particular limitation and may be properly selected according to contemplated purposes. Examples of such other steps include a base material surface treatment step, a development step, a curing treatment step, and a post exposure step.

### <<Development Step>>

The development is carried out by removing unexposed areas of the photoselective layer.

The unexposed areas may be removed by any method without particular limitation, and the method may be properly selected according to contemplated purposes. Examples of such method include a method that removes the unexposed areas with a developing solution.

The developing solution is not particularly limited and may be properly selected according to contemplated purposes. Examples thereof include aqueous alkaline solutions, aqueous developing solutions, and organic solvents. Among them, weakly alkaline aqueous solutions are particularly preferred. Examples of base ingredients in weakly alkaline aqueous solutions include lithium hydroxide, sodium hydroxide, potassium hydroxide, lithium carbonate, sodium carbonate, potassium carbonate, lithium hydrogencarbonate, sodium hydrogencarbonate, potassium hydrogencarbonate, sodium phosphate, potassium phosphate, sodium pyrophosphate, potassium pyrophosphate, and borax.

Preferably, the weakly alkaline aqueous solution has a pH value of, for example, 8 to 12, more preferably 9 to 11. Examples of the weakly alkaline aqueous solutions include 0.1% by mass to 5% by mass aqueous sodium carbonate or potassium carbonate solutions.

The temperature of the developing solution may be properly selected according to the developability of the photoselective layer and is, for example, preferably about 25° C. to about 40° C.

The developing solution may be used in combination with surfactants, antifoaming agents, organic bases (for example, ethylenediamine, ethanolamine, tetramethylammonium hydroxide, diethylenetriamine, triethylenepentamine, morpholine, and triethanolamine) and organic solvents for accelerating development (for example, alcohols, ketones, esters, ethers, amides, and lactones). The development solution may be an aqueous developing solution obtained by mixing water or an aqueous alkali solution with an organic solvent, or alternatively, an organic solvent may be used solely as the developing solution.

### <<Curing Treatment Step>>

In the curing treatment step, after the development step, the patterned photosensitive layer is cured.

The curing treatment step is not particularly limited and may be properly selected according to contemplated purposes. Suitable examples of the curing treatment step include whole area exposure treatment and whole area heating treatment.

Examples of whole area exposure methods include a method in which, after the development, the whole area on the laminate with the permanent pattern formed thereon is exposed. In the whole area exposure, the curing of the resin in the photosensitive composition constituting the photosensitive layer is accelerated to cure the surface of the permanent pattern.

The whole area exposure may be carried out by any apparatus without particular limitation, and the apparatus may be properly selected according to contemplated purposes. Examples thereof include UV (ultraviolet) exposure apparatuses such as ultrahigh-pressure mercury lamps.

Examples of whole area heating treatment methods include a method in which, after the development, the whole area on the laminate with the permanent pattern formed thereon is heated. The whole area heating can enhance the film strength of the surface of the permanent pattern.

The heating temperature in the whole area heating is preferably 120° C. to 250° C., more preferably 120° C. to 200° C. When the heating temperature is 120° C. or above, the heating treatment can improve the film strength. When the heating temperature is 250° C. or below, weakening and embrittlement of the film as a result of the decomposition of the resin in the photosensitive composition can be prevented.

The heating time in the whole area heating is preferably 10 min to 120 min, more preferably 15 min to 60 min.

The whole area heating may be carried out by any apparatus without particular limitation, and the apparatus may be properly selected from conventional apparatuses according to contemplated purposes. Examples thereof include dry ovens, hot plates, and IR (infrared) heaters.

When the permanent pattern is formed by a method for forming a permanent pattern that forms at least any of a protective film, an interlayer insulating film, and a solder resist pattern, a method may be adopted in which a permanent pattern is formed by the method for forming a permanent pattern on a printed wiring board followed by soldering by the following method.

Specifically, a curing layer as the permanent pattern is formed by the development, and a metal layer is exposed on the surface of the printed wiring board, the metal layer site exposed on the surface of the printed wiring board is plated with gold and is then soldered. A semiconductor or a component is mounted at the soldered site. At that time, the permanent pattern formed of the cured layer functions as a protective film, an insulating film (an interlayer insulating film), or a solder resist and can protect the assembly against external impact or conduction between adjacent electrodes.

### (Printed Board)

The printed board according to the present invention includes at least a substrate, a permanent pattern formed by the method for forming a permanent pattern and further properly selected optional other elements.

The other elements are not particularly limited and may be properly selected according to contemplated purposes. Examples thereof include an insulating layer additionally provided between the base material and the permanent pattern to constitute a build-up board.

### EXAMPLES

The present invention will be described with reference to the following Examples. However, it should be noted that the present invention is not limited to these Examples.

### Synthesis Example 1

### Synthesis of Photosensitive Polyurethane Resin U1

10.22 g (0.069 mol) of 2,2-bis(hydroxymethyl) butanoic acid (DMBA), 12.97 g (0.081 mol) of glycerol monomethacrylate (GLM), and 4.80 g (0.004 mol) of polypropylene glycol (molecular weight: 1,200) (PPG 1,200) were dissolved in 79 mL of propylene glycol monomethyl ether monoacetate in a 500 mL three-necked round flask equipped with a condenser and a stirrer. To the solution, 37.54 g (0.15 mol) of 4,4-diphenylmethane diisocyanate (MDI), 0.1 g of 2,6-di-t-butylhydroxytoluene, and, as a catalyst, 0.2 g of NEOSTAN U-600 (manufactured by Nitto Kasei Co. Ltd.) were added, and the mixture was stirred at 75° C. for 5 hr. Thereafter, the solution was diluted with 9.61 mL of methyl alcohol, and the resultant diluted solution was stirred for 30 min to obtain 145 g of photosensitive polyurethane resin U1 solution (solid content: 45% by mass).

The photosensitive polyurethane resin U1 thus obtained had an acid value of 65 mgKOH/g, a mass average molecular weight (using a polystyrene standard) of 15,000 as measured by gel permeation chromatography (GPC), and a vinyl group equivalent of 1.26 mmol/g.

The acid value was measured according to JIS K 0070. When the sample did not melt, for example, dioxane or tetrahydrofuran was used as a solvent.

The mass average molecular weight was measured with a high-speed gel permeation chromatography (GPC) (HLC-802A, manufactured by TOSOH Co., Ltd.). Specifically, a 0.5% by mass THF solution was used as a sample solution. 62 columns of TSKgel GMH were provided. The sample (200 μL) was injected and eluted with the THF solution, followed by measurement at 25° C. with a refractive index detector. The mass average molecular weight was determined with a molecular weight distribution curve that had been calibrated using standard polystyrene.

The vinyl group equivalent was determined by measuring a bromine value according to JIS K 2605.

### Synthesis Example 2

### Synthesis of Photosensitive Polyurethane Resin U2 (when Diisocyanate Compound is Free of Aromatic Compound)

A photosensitive polyurethane resin U2 solution (solid content: 45% by mass) was produced in the same manner as in Synthesis Example 1, except that 37.54 g (0.15 mol) of 4,4-diphenylmethane diisocyanate (MDI) was changed to 30.03 g (0.12 mol) of isophoronediisocyanate (IPDI).

### Synthesis Example 3

### Synthesis of Photosensitive Polyurethane Resin U3 (when Polymer Polyol Compound Has the Mass Average Molecular Weight of Less than 400)

A photosensitive polyurethane resin U3 solution (solid content: 45% by mass) was produced in the same manner as in Synthesis Example 1, except that 4.80 g (0.004 mol) of polypropylene glycol (mass average molecular weight: 1,200) (PPG1200) was changed to 1.20 g (0.004 mol) of polypropylene glycol (mass average molecular weight: 300) (PPG300).

### Synthesis Example 4

### Synthesis of Photosensitive Polyurethane Resin U4 (when the Polymer Polyol Compound has the Mass Average Molecular Weight of More than 3,000)

A photosensitive polyurethane resin U4 solution (solid content: 45% by mass) was produced in the same manner as in Synthesis Example 1, except that 4.80 g (0.004 mol) of polypropylene glycol (mass average molecular weight: 1,200) (PPG1200) was changed to 14.00 g (0.004 mol) of polypropylene glycol (mass average molecular weight: 3,500) (PPG3500).

### Example 1

### Production of Photosensitive Film

The photosensitive composition solution having the below composition was coated onto a 16 μm-thick polyethylene terephthalate film (16FB50, manufactured by Toray Co., Ltd.) as a support, and the coating was dried to form a 30 μm-thick photosensitive layer on the support. A 20 μm-thick polypropylene film (ALPHAN E-200, manufactured by Oji Specialty Paper Co. Ltd.) was laminated as a protective layer on the photosensitive layer to produce a photosensitive film.

### Composition of Photosensitive Composition Solution—

| Photosensitive polyurethane resin U1 solution of | 90 | parts by |
|---|---|---|
| Synthesis Example 1 (solid content: 45% by mass) | mass | |
| Polymerizable compound (A-DPH manufactured by | 11.15 | parts by |
| Shin-Nakamura Chemical Co., Ltd.) | mass | |
| Thermal crosslinking agent (EPOTOTO YDF-170, | 2.0 | parts by |
| manufactured by Tohto Kasei Co., Ltd., | mass | |
| Bisphenol F epoxy resin) | | |
| Photopolymerization initiator represented by the | 1.0 | part by |
| following formula (trade name: IRGACURE 907, | mass | |
| manufactured by Ciba Specialty Chemicals) | | |
| 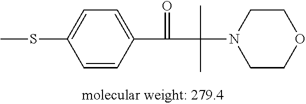 | | |
| Metal phosphate (OP-935, manufactured by Clariant | 20 | parts by |
| (Japan) K.K.) | mass | |
| Pigment dispersion (hereinafter referred to as “G-1”) | 36.1 | parts by |
| | mass | |
| 30% by mass solution of MEGAFAC F-780F | 0.13 | parts by |
| (manufactured by Dainippon Ink and Chemicals, Inc.) | mass | |
| in methyl ethyl ketone | | |
| Methyl ethyl ketone (solvent) | 12.0 | parts by |

mass

Notably, the pigment dispersion (G-1) was prepared by premixing 48.2 parts by mass of photosensitive polyurethane resin U1 solution of Synthesis Example 1 (solid content: 45% by mass), 0.51 part by mass of phthalocyanine blue, 0.14 parts by mass of the anthraquinone yellow pigment (C.I. PY24), and 25.5 parts by mass of n-propyl acetate and dispersing them with zirconia beads having a diameter of 1.0 mm at a peripheral speed of 9 m/sec for 3 hr with MOTOR MILL M-250 (manufactured by Eiger).

### —Laminating on Substrate—

The surface of a copper clad laminate (throughhole-free laminate, copper thickness: 12 μm) was chemically polished to prepare a substrate. The photosensitive film was laminated on the copper clad laminate with a vacuum laminator (VP130, manufactured by Nichigo-Morton Co., Ltd.) while peeling off the protective film from the photosensitive film so that the photosensitive layer in the photosensitive film was brought into contact with the copper clad laminate. Thus, a photosensitive laminate including the copper clad laminate, the photosensitive layer, and the polyethylene terephthalate film (support) laminated in that order was prepared.

Contact bonding was carried out under conditions of a vacuuming time of 40 sec, a contact bonding temperature of 70° C., a contact bonding pressure of 0.2 MPa, and a pressing time of 10 sec.

With respect to the thus-obtained laminate, folding resistance and flame retardancy were evaluated as follows. The results are shown in Table 1.

### <Folding Resistance>

For measuring folding resistance, a dry film resist was laminated on a board for a flexible printing wiring board (trade name: ESPANEX MB series, manufactured by Nippon Steel Chemical Co., Ltd.) in which a copper foil with thickness 18 μm was laminated on a polyimide base material (thickness: 25 μm). The resultant laminate was subjected to exposure to light at 200 mJ, followed by development under the condition of 0.15 MPa/90 s, to produce a line pattern with Line/Space =100/100 μm.

To the thus-obtained polyimide with copper foil line pattern, the above-produced photosensitive composition layer was laminated to the side of the copper foil line pattern, followed by subjecting to exposure to light at 1,000 mJ, to obtain a laminate for evaluation.

The resultant laminate for evaluation was bent at 180 degrees with the line pattern side facing the outside. A weight of 100 g or 200 g was placed on the resultant bent portion, and folding resistance was evaluated according to the following criteria.

### [Evaluation Criteria]

A: A sample which could withstand the weight of 200 g

B: A sample which could withstand the weight of 100 g, but which could not withstand the weight of 200 g

C: A sample which could not withstand the weight of 100 g

### <Flame Retardancy>

A photosensitive composition layer was laminated onto the both sides with copper foil line patterns of a board for a flexible printing wiring board (trade name: ESPANEX MB series, manufactured by Nippon Steel Chemical Co., Ltd.) in which two copper foils with thickness 18 μm were laminated on a polyimide base material (thickness: 12.5 μm), followed by subjecting to exposure to light at 1,000 mJ, to obtain a laminate for evaluation.

The laminate was evaluated with a test in accordance with UL94 thin material vertical firing test. The laminate was ranked as any one of VTM-0, VTM-1, VTM-2, or NOT in accordance with UL94. The “NOT” means that the sample was burned to a marked line. Notably, the laminate has excellent flame retardancy in the following order: VTM-0>VTM-1>VTM-2>NOT.

### Example 2

The photosensitive film, laminate, and permanent pattern of Example 2 were produced in the same manner as in Example 1, except that the metal phosphate (OP-935, manufactured by Clariant (Japan) K.K.) was changed to a phosphazene compound (SPS-100, manufactured by Otsuka Chemical Co., Ltd.).

The thus-obtained laminate was subjected to the evaluations for folding resistance and flame retardancy in the same manner as in Example 1. The results are shown in Table 1.

### Example 3

The photosensitive film, laminate, and permanent pattern of Example 3 were produced in the same manner as in Example 1, except that the metal phosphate (OP-935, manufactured by Clariant (Japan) K.K.) was changed to a condensed phosphoric acid compound (FP-600, manufactured by Adeka Corporation).

The thus-obtained laminate was subjected to the evaluations for folding resistance and flame retardancy in the same manner as in Example 1. The results are shown in Table 1.

### Example 4

The photosensitive film, laminate, and permanent pattern of Example 4 were produced in the same manner as in Example 1, except that 90 parts by mass of the photosensitive polyurethane resin U1 solution of Synthesis Example 1 (solid content: 45% by mass) was changed to 60 parts by mass of the photosensitive polyurethane resin U1 solution of Synthesis Example 1 (solid content: 45% by mass) and 30 parts by mass of a bisphenyl epoxy acrylate resin solution (ZCR-1569H, manufactured by Nippon Kayaku Co., Ltd.).

The thus-obtained laminate was subjected to the evaluations for folding resistance and flame retardancy in the same manner as in Example 1. The results are shown in Table 1.

### Example 5

The photosensitive film, laminate, and permanent pattern of Example 5 were produced in the same manner as in Example 1, except that the metal phosphate (OP-935, manufactured by Clariant (Japan) K.K.) was changed to a polyphosphoric acid melamine salt (FCP-770, manufactured by Suzuhiro Chemical Co., Ltd.).

The thus-obtained laminate was subjected to the evaluations for folding resistance and flame retardancy in the same manner as in Example 1. The results are shown in Table 1.

### Example 6

The photosensitive film, laminate, and permanent pattern of Example 6 were produced in the same manner as in Example 1, except that the photosensitive polyurethane resin U1 solution of Synthesis Example 1 (solid content: 45% by mass) was changed to the photosensitive polyurethane resin U2 solution of Synthesis Example 2 (solid content: 45% by mass).

The thus-obtained laminate was subjected to the evaluations for folding resistance and flame retardancy in the same manner as in Example 1. The results are shown in Table 1.

### Example 7

The photosensitive film, laminate, and permanent pattern of Example 7 were produced in the same manner as in Example 1, except that the photosensitive polyurethane resin U1 solution of Synthesis Example 1 (solid content: 45% by mass) was changed to the photosensitive polyurethane resin U3 solution of Synthesis Example 3 (solid content: 45% by mass).

The thus-obtained laminate was subjected to the evaluations for folding resistance and flame retardancy in the same manner as in Example 1. The results are shown in Table 1.

### Example 8

The photosensitive film, laminate, and permanent pattern of Example 8 were produced in the same manner as in Example 1, except that the photosensitive polyurethane resin U1 solution of Synthesis Example 1 (solid content: 45% by mass) was changed to the photosensitive polyurethane resin U4 solution of Synthesis Example 4 (solid content: 45% by mass).

The thus-obtained laminate was subjected to the evaluations for folding resistance and flame retardancy in the same manner as in Example 1. The results are shown in Table 1.

### Comparative Example 1

The photosensitive film, laminate, and permanent pattern of Comparative Example 1 were produced in the same manner as in Example 1, except that the photosensitive polyurethane resin U1 solution of Synthesis Example 1 (solid content: 45% by mass) was changed to a polyurethane resin solution (UXE-3024, manufactured by Nippon Kayaku Co., Ltd., solid content: 45% by mass, free of polymer polyol structure).

The thus-obtained laminate was subjected to the evaluations for folding resistance and flame retardancy in the same manner as in Example 1. The results are shown in Table 1.

### Comparative Example 2

The photosensitive film, laminate, and permanent pattern of Comparative Example 2 were produced in the same manner as in Example 1, except that 90 parts by mass of the photosensitive polyurethane resin U1 solution of Synthesis Example 1 (solid content: 45% by mass) was changed to 60 parts by mass of the polyurethane resin solution (UXE-3024, manufactured by Nippon Kayaku Co., Ltd., solid content: 45% by mass, free of polymer polyol structure) and 30 parts by mass of the bisphenyl epoxy acrylate resin solution(ZCR-1569H, manufactured by Nippon Kayaku Co., Ltd.).

The thus-obtained laminate was subjected to the evaluations for folding resistance and flame retardancy in the same manner as in Example 1. The results are shown in Table 1.

### Comparative Example 3

The photosensitive film, laminate, and permanent pattern of Comparative

Example 3 were produced in the same manner as in Example 1, except that the photosensitive polyurethane resin U1 solution of Synthesis Example 1 (solid content: 45% by mass) was changed to a bisphenol A epoxy acrylate resin solution (trade name: ZAR-1401H, manufactured by Nippon Kayaku Co., Ltd., solid content: 45% by mass).

The thus-obtained laminate was subjected to the evaluations for folding resistance and flame retardancy in the same manner as in Example 1. The results are shown in Table 1.

### Comparative Example 4

The photosensitive film, laminate, and permanent pattern of Comparative Example 4 were produced in the same manner as in Example 1, except that 90 parts by mass of the photosensitive polyurethane resin U1 solution of Synthesis Example 1 (solid content: 45% by mass) was changed to 30 parts by mass of the bisphenyl epoxy acrylate resin solution (ZCR-1569H, manufactured by Nippon Kayaku Co., Ltd., solid content: 45% by mass) and 60 parts by mass of the bisphenol A epoxy acrylate resin solution (ZAR-1401H, manufactured by Nippon Kayaku Co., Ltd., solid content: 45% by mass).

The thus-obtained laminate was subjected to the evaluations for folding resistance and flame retardancy in the same manner as in Example 1. The results are shown in Table 1.

### Comparative Example 5

The photosensitive film, laminate, and permanent pattern of Comparative Example 5 were produced in the same manner as in Example 1, except that the photosensitive polyurethane resin U1 solution of Synthesis Example 1 (solid content: 45% by mass) was changed to a bisphenol F epoxy acrylate resin solution (ZFR-1491H, manufactured by Nippon Kayaku Co., Ltd., solid content: 45% by mass).

The thus-obtained laminate was subjected to the evaluations for folding resistance and flame retardancy in the same manner as in Example 1. The results are shown in Table 1.

### Comparative Example 6

The photosensitive film, laminate, and permanent pattern of Comparative Example 6 were produced in the same manner as in Example 1, except that 90 parts by mass of the photosensitive polyurethane resin U1 solution of Synthesis

Example 1 (solid content: 45% by mass) was changed to 30 parts by mass of the bisphenyl epoxy acrylate resin solution (ZCR-1569H, manufactured by Nippon Kayaku Co., Ltd., solid content: 45% by mass) and 60 parts by mass of the bisphenol F epoxy acrylate resin solution (ZFR-1491H, manufactured by Nippon Kayaku Co., Ltd., solid content: 45% by mass).

The thus-obtained laminate was subjected to the evaluations for folding resistance and flame retardancy in the same manner as in Example 1. The results are shown in Table 1.

### Comparative Example 7

The photosensitive film, laminate, and permanent pattern of Comparative Example 7 were produced in the same manner as in Example 1, except that the metal phosphate (OP-935, manufactured by Clariant (Japan) K.K.) was not added.

The thus-obtained laminate was subjected to the evaluations for folding resistance and flame retardancy in the same manner as in Example 1. The results are shown in Table 1.

### Comparative Example 8

The photosensitive film, laminate, and permanent pattern of Comparative Example 8 were produced in the same manner as in Comparative Example 1, except that the metal phosphate (OP-935, manufactured by Clariant (Japan) K.K.) was not added.

The thus-obtained laminate was subjected to the evaluations for folding resistance and flame retardancy in the same manner as in Example 1. The results are shown in Table 1.

TABLE 1-1

| | | | | | | Comp. |
|---|---|---|---|---|---|---|
| Ingredient (% by mass) | | Ex. 1 | Ex. 6 | Ex. 7 | Ex. 8 | Ex. 1 |
| Resin | Polyurethane resin U1 solution of | 90 | — | — | — | — |
| | Synthesis Example 1 | | | | | |
| | Polyurethane resin U2 solution of | — | 90 | — | — | — |
| | Synthesis Example 2 | | | | | |
| | Polyurethane resin U3 solution of | — | — | 90 | — | — |
| | Synthesis Example 3 | | | | | |
| | Polyurethane, resin U4 solution of | — | — | — | 90 | — |
| | Synthesis Example 4 | | | | | |
| | Polyurethane resin (UXE-3024) | — | — | — | — | 90 |
| | solution | | | | | |
| Flame | Metal phosphate (OP-935) | 20 | 20 | 20 | 20 | 20 |
| retardant | Phosphazene compound | — | — | — | — | — |
| | Condensed phosphoric acid | — | — | — | — | — |
| | compound | | | | | |
| | Polyphosphoric acid melamine salt | — | — | — | — | — |
| Evaluation | Folding resistance | A | A | B | A | B |
| result | Flame retardancy | VTM-0 | VTM-1 | VTM-0 | VTM-0 | NOT |

TABLE 1-2

| | | | Comp. | Comp. | Comp. |
|---|---|---|---|---|---|
| Ingredient (% by mass) | | Ex. 1 | Ex. 1 | Ex. 7 | Ex. 8 |
| Resin | Polyurethane resin | 90 | — | 90 | — |
| | U1 solution of | | | | |
| | Synthesis Example 1 | | | | |
| | Polyurethane resin | — | 90 | — | 90 |
| | (UXE-3024) solution | | | | |
| Flame | Metal phosphate | 20 | 20 | — | — |
| retardant | (OP-935) | | | | |
| | Phosphazene | — | — | — | — |
| | compound | | | | |
| | Condensed phosphoric | — | — | — | — |
| | acid compound | | | | |
| | Polyphosphoric acid | — | — | — | — |
| | melamine salt | | | | |
| Evaluation | Folding resistance | A | B | A | B |
| result | Flame retardancy | VTM-0 | NOT | NOT | NOT |

TABLE 1-3

| Ingredient (% by mass) | | Ex. 1 | Ex. 2 | Ex. 3 | Ex. 5 |
|---|---|---|---|---|---|
| Resin | Polyurethane resin | 90 | 90 | 90 | 90 |
| | U1 solution of | | | | |
| | Synthesis Example 1 | | | | |
| Flame | Metal phosphate | 20 | — | — | — |
| retardant | (OP-935) | | | | |
| | Phosphazene | — | 20 | — | — |
| | compound | | | | |
| | Condensed phosphoric | — | — | 20 | — |
| | acid compound | | | | |
| | Polyphosphoric acid | — | — | — | 20 |
| | melamine salt | | | | |
| Evaluation | Folding resistance | A | A | A | A |
| result | Flame retardancy | VTM-0 | VTM-0 | VTM-1 | VTM-0 |

TABLE 1-4

| | | | Comp. |
|---|---|---|---|
| Ingredient (% by mass) | | Ex. 4 | Ex. 2 |
| Resin | Polyurethane resin U1 solution | 60 | — |
| | of Synthesis Example 1 | | |
| | Polyurethane resin (UXE-3024) solution | — | 60 |
| | Biphenyl epoxyacrylate resin solution | 30 | 30 |
| | Bisphenol A epoxyacrylate resin solution | — | — |
| | Bisphenol F epoxyacrylate resin solution | — | — |
| Flame | Metal phosphate (OP-935) | 20 | 20 |
| retardant | Phosphazene compound | — | — |
| | Condensed phosphoric acid compound | — | — |
| | Polyphosphoric acid melamine salt | — | — |
| Evaluation | Folding resistance | A | C |
| result | Flame retardancy | VTM-0 | VTM-0 |

TABLE 1-5

| | | Comp. | Comp. | Comp. | Comp. |
|---|---|---|---|---|---|
| Ingredient (% by mass) | | Ex. 3 | Ex. 4 | Ex. 5 | Ex. 6 |
| Resin | Polyurethane resin | — | — | — | — |
| | U1 solution of | | | | |
| | Synthesis Example 1 | | | | |
| | Polyurethane resin | — | — | — | — |
| | (UXE-3024) solution | | | | |
| | Biphenyl | — | 30 | — | 30 |
| | epoxyacrylate | | | | |
| | resin solution | | | | |
| | Bisphenol A | 90 | 60 | — | — |
| | epoxyacrylate | | | | |
| | resin solution | | | | |
| | Bisphenol F | — | — | 90 | 60 |
| | epoxyacrylate | | | | |
| | resin solution | | | | |
| Flame | Metal phosphate | 20 | 20 | 20 | 20 |
| retardant | (OP-935) | | | | |
| | Phosphazene | — | — | — | — |
| | compound | | | | |
| | Condensed phosphoric | — | — | — | — |
| | acid compound | | | | |
| | Polyphosphoric acid | — | — | — | — |
| | melamine salt | | | | |
| Evaluation | Folding resistance | B | B | B | B |
| result | Flame retardancy | NOT | VTM-1 | NOT | VTM-0 |

### INDUSTRIAL APPLICABILITY

The photosensitive composition according to the present invention has excellent folding resistance and flame retardancy and thus is suitable for use in solder resists.

The photosensitive film according to the present invention has improved folding resistance and flame retardancy and can efficiently form a high definition permanent pattern and thus is suitable for use in the formation of various patterns, for example, permanent patterns such as protective films, interlayer insulating films, and solder resist patterns; the formation of semiconductor packages such as BGAs (ball grid arrays), CSPs (chip size packages), and TCPs (tape carrier packages); the production of liquid crystal structural members such as color filters, columnar materials, rib materials, spacers, and partition walls; holograms, micromachines, and proofs and is particularly suitable for use in the formation of permanent patterns in printed boards, and the formation of semiconductor packages such as BGAs (ball grid arrays), CSPs (chip size packages), and TCPs (tape carrier packages).

The method for pattern formation according to the present invention uses the photosensitive composition and thus is suitable for use in the formation of semiconductor packages, such as BGAs (ball grid arrays), CSPs (chip size packages), and TCPs (tape carrier packages); the formation of various patterns, for example, permanent patterns such as protective films, interlayer insulating films, and solder resist patterns; the production of liquid crystal structural members such as color filters, columnar materials, rib materials, spacers, and partition walls; holograms, micromachines, and proofs and is particularly suitable for use in the formation of permanent patterns in printed boards and the formation of semiconductor packages, such as BGAs (ball grid arrays), CSPs (chip size packages), and TCPs (tape carrier packages).

1. A photosensitive composition comprising:
a photosensitive polyurethane resin;
a phosphorus-containing flame retardant;
a polymerizable compound; and
a photopolymerization initiator,
wherein the photosensitive polyurethane resin contains an ethylenically unsaturated bond group and a carboxyl group, and contains a polyurethane skeleton which contains a repeating unit derived from a polyol.

2. The photosensitive composition according to claim 1, wherein the ethylenically unsaturated bond group is a (meth)acrylate group.

3. The photosensitive composition according to claim 1, wherein the photosensitive polyurethane resin is obtained by reacting together a polymer polyol compound, a diisocyanate compound, a (meth)acrylate compound having two hydroxy groups in a molecule thereof, and a carboxylic acid having two hydroxy groups in a molecule thereof.

4. The photosensitive composition according to claim 3, wherein the polymer polyol compound is a polypropylene glycol.

5. The photosensitive composition according to claim 3, wherein the polymer polyol compound has a mass average molecular weight of 400 to 3,000.

6. The photosensitive composition according to claim 3, wherein the diisocyanate compound is an aromatic compound.

7. The photosensitive composition according to claim 3, wherein the diisocyanate compound is a diisocyanate compound having a bisphenol A skeleton, a bisphenol F skeleton, a bisphenyl skeleton, a naphthalene skeleton, a phenanthrene skeleton, or an anthracene skeleton.

8. The photosensitive composition according to claim 1, wherein the phosphorus-containing flame retardant is a condensed phosphoric acid compound, a polyphosphoric acid melamine salt, a phosphazene compound, and a metal phosphate.

9. The photosensitive composition according to claim 1, further comprising a thermal crosslinking agent.

10. A photosensitive film comprising:
a support; and
a photosensitive layer which contains a photosensitive composition, the photosensitive layer being provided on the support,
wherein the photosensitive composition comprises:
a photosensitive polyurethane resin;
a phosphorus-containing flame retardant;
a polymerizable compound; and
a photopolymerization initiator, and
wherein the photosensitive polyurethane resin contains an ethylenically unsaturated bond group and a carboxyl group, and contains a polyurethane skeleton which contains a repeating unit derived from a polyol.

11. A method for forming a permanent pattern, the method comprising:
exposing, to light, a photosensitive layer formed of a photosensitive composition,
wherein the photosensitive composition comprises:
a photosensitive polyurethane resin;
a phosphorus-containing flame retardant;
a polymerizable compound; and
a photopolymerization initiator, and
wherein the photosensitive polyurethane resin contains an ethylenically unsaturated bond group and a carboxyl group, and contains a polyurethane skeleton which contains a repeating unit derived from a polyol.

12. (canceled)

13. (canceled)
